(19) United States
(12) Patent Application Publication
(10) Pub. No.: US 2026/0198364 A1
(43) Pub. Date: Jul. 9, 2026

(54) SEMICONDUCTOR DEVICE

(71) Applicant: ROHM CO., LTD., Kyoto-shi (JP)

(72) Inventors: Tomoya SAKAI, Kyoto-shi (JP); Shojiro KATO, Kyoto-shi (JP); Toru TAKUMA, Kyoto-shi (JP); Naoki TAKAHASHI, Kyoto-shi (JP)

(21) Appl. No.: 19/556,485

(22) Filed: Mar. 4, 2026

Related U.S. Application Data
(63) Continuation of application No. PCT/JP2024/026631, filed on Jul. 25, 2024.

(30) Foreign Application Priority Data
Sep. 6, 2023 (JP) 2023-144163

(51) Int. Cl. H10W 72/90; H10W 40/20; H10W 70/40; H10W 74/00; H10W 90/00

(52) U.S. Cl. CPC H10W 72/9445; H10W 40/233; H10W 70/417; H10W 70/481; H10W 74/00; H10W 90/756

(57) ABSTRACT

A semiconductor device includes a semiconductor element including a surface electrode formed on the element surface thereof. The element surface includes an active region in which power transistors are formed, and a control circuit region in which a control circuit for controlling the power transistors is formed. The active region is formed so as to surround the control circuit region from both sides in a second direction and one side in a first direction. The surface electrode is disposed on the active region at a position different from the control circuit region, and is formed so as to surround the control circuit region from both sides in the second direction and one side in the first direction when viewed from the thickness direction thereof.

### CROSS-REFERENCE TO RELATED APPLICATIONS

This application is a continuation of, and claims the benefit of priority from International Application No. PCT/JP2024/026631, filed on July 25, 2024, which claims the benefit of priority from Japanese Patent Application No. 2023-144163, filed on September 6, 2023, the entire contents of each of which are incorporated herein by reference.

### BACKGROUND

The present disclosure relates to a semiconductor device.

JP2017-147433A discloses a semiconductor device including a switching circuit formed in an active region, an over charge current detection circuit, a thermal shut down circuit, and an under voltage lock-out circuit that are formed in a surface portion of a single substrate.

### BRIEF DESCRIPTION OF DRAWINGS

FIG. 1 A schematic perspective view of a semiconductor device in a first embodiment.

FIG. 2 A schematic plan view showing the internal structure of the semiconductor device shown in FIG. 1.

FIG. 3 A schematic bottom view of the semiconductor device shown in FIG. 1.

FIG. 4 A schematic cross-sectional view showing the structure of the semiconductor device taken along line F4-F4 in FIG. 2.

FIG. 5 A schematic circuit diagram of the semiconductor device shown in FIG. 1.

FIG. 6 A schematic plan view showing the semiconductor element when a surface electrode and a passivation film are removed from the semiconductor device shown in FIG. 2.

FIG. 7 A schematic plan view of the semiconductor element shown in FIG. 2.

FIG. 8 A schematic plan view of the semiconductor element shown in FIG. 2 to which electrode connectors of wires are connected.

FIG. 9 A schematic plan view of the semiconductor element in FIG. 2 to which the wires are connected.

FIG. 10 A schematic cross-sectional view of the semiconductor element taken along line F10-F10 in FIG. 9.

FIG. 11 A schematic plan view showing the internal structure of a semiconductor device in a second embodiment.

FIG. 12 A schematic plan view of the semiconductor element when a surface electrode and a passivation film are removed from the semiconductor device shown in FIG. 11.

FIG. 13 A schematic plan view of the semiconductor element shown in FIG. 12, additionally showing the surface electrode and the passivation film.

FIG. 14 A schematic plan view of the semiconductor element shown in FIG. 13 to which electrode connectors of wires are connected.

FIG. 15 A schematic plan view of the semiconductor element in FIG. 13 to which the wires are connected.

FIG. 16 A schematic plan view of a semiconductor element to which electrode connectors of wires are connected in a modified example of a semiconductor device.

### DETAILED DESCRIPTION

Embodiments of a semiconductor device according to the present disclosure will now be described with reference to the accompanying drawings. In the drawings, components may not be drawn to scale for simplicity and clarity of illustration. To facilitate understanding, hatching lines may not be shown in the cross-sectional drawings. The accompanying drawings only illustrate embodiments of the present disclosure and are not intended to limit the present disclosure. Terms such as “first”, “second”, and “third” in this disclosure are used to distinguish subjects and are not used for ordinal purposes.

This detailed description includes exemplary embodiments of devices, systems, and methods in accordance with the present disclosure. Further, this detailed description is illustrative and is not intended to limit embodiments of the present disclosure or application and use of the embodiments.

In this specification, the phrase “at least one of” as used in this disclosure means “one or more” of desired choices. As one example, the phrase “at least one of” as used in this disclosure includes “only one of the two choices” and “both of the two choices” in a case where the number of choices is two. In another example, the phrase “at least one of” means “only one of the choices” or “any combination of two or more of the choices” if the number of choices is three or more.

In this specification, phrases such as “the length (dimension) of A is equal to the length (dimension) of B” and “A and B are equal in length (dimension)” encompass a relationship in which a difference between the length of A and the length of B is, for example, 10% of the length of A or less.

### First Embodiment

### Overall Structure of Semiconductor Device

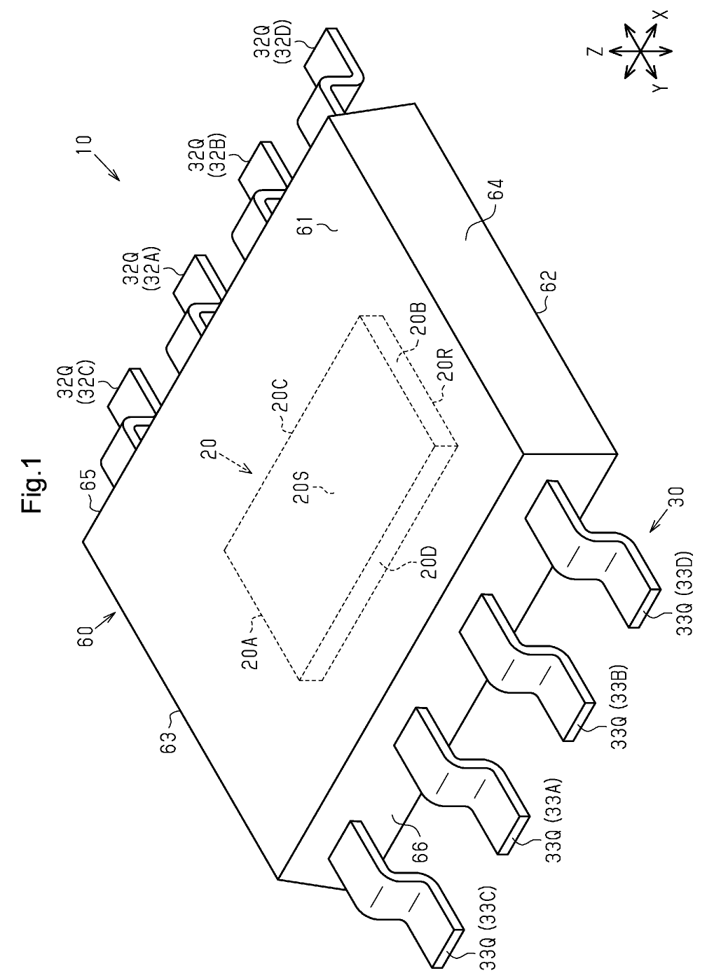

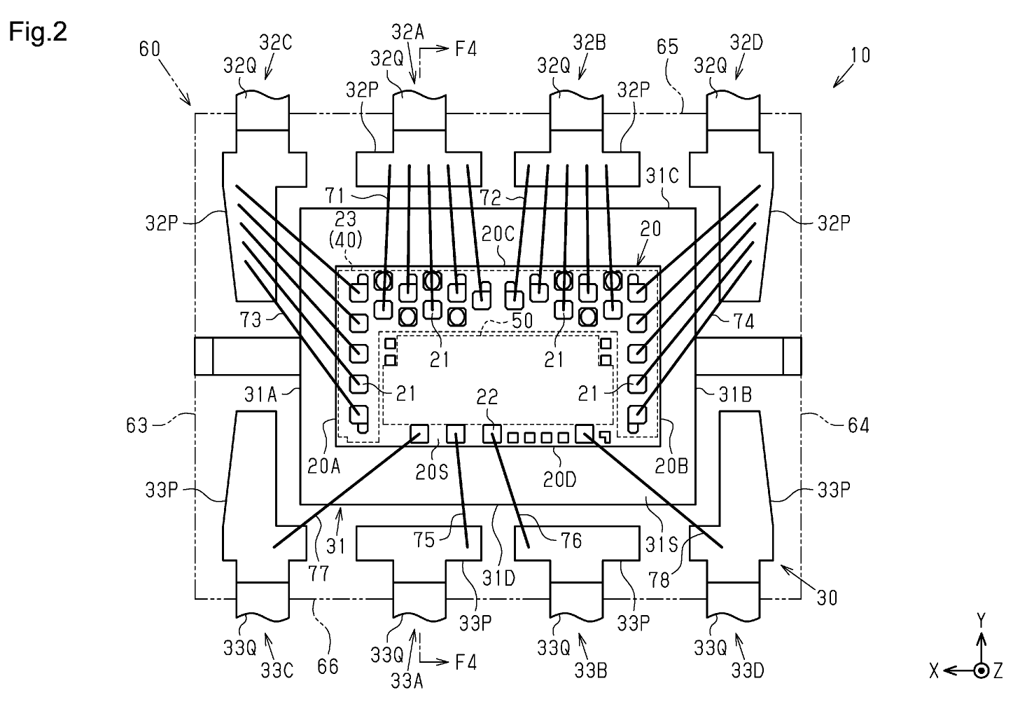

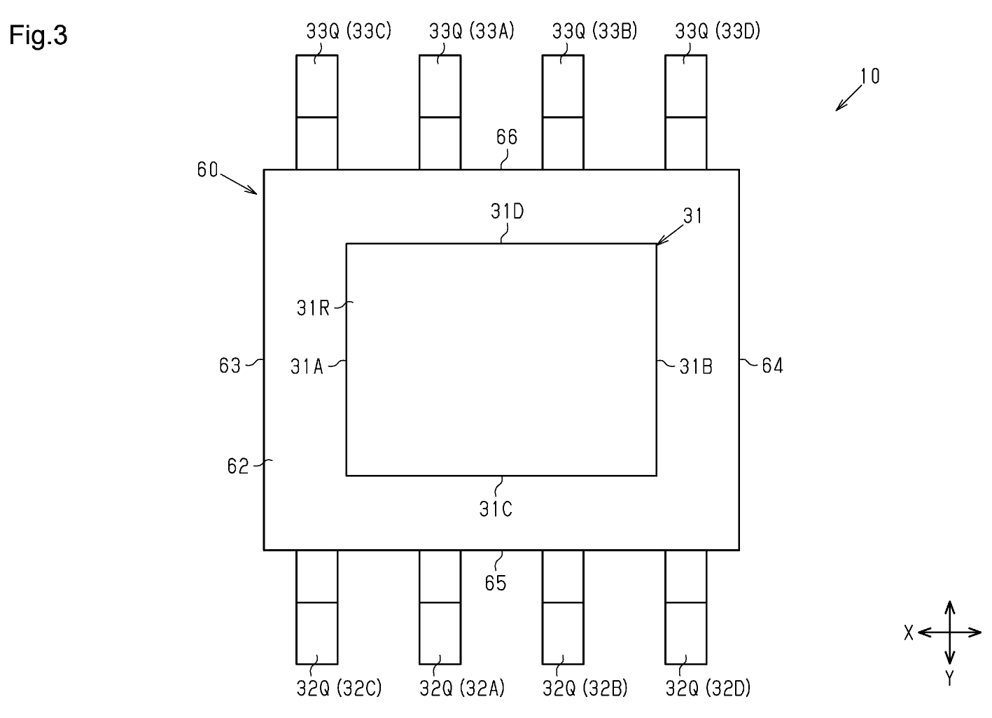

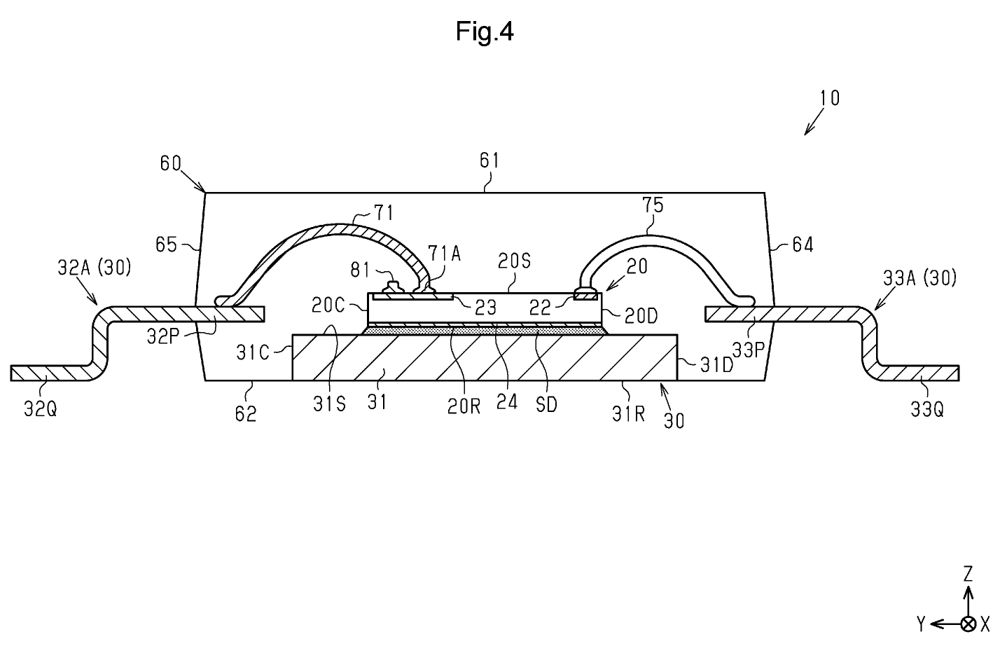

An overall structure of a first embodiment of a semiconductor device 10 will now be described with reference to FIGS. 1 to 4. FIG. 1 shows a schematic perspective view of the structure of the semiconductor device 10 in the first embodiment. FIG. 2 is a schematic plan view of the internal structure of the semiconductor device 10 shown in FIG. 1. FIG. 3 shows a schematic bottom structure of the semiconductor device 10 shown in FIG. 1. FIG. 4 shows a schematic cross-sectional structure of the semiconductor device 10 taken along line F4-F4 shown in FIG. 2. In FIG. 2, an encapsulation resin 60, which will be described later, is indicated by double-dashed lines, and components arranged in the encapsulation resin 60 are indicated by solid lines to show the inner structure of the semiconductor device 10. The term “plan view” used in the present disclosure refers to a view of the semiconductor device 10 in the Z-direction when the XYZ-axes are orthogonal to each other as shown in FIG. 1. In the present disclosure, the X-direction is an example of a “second direction.” The Y-direction is an example of a “first direction.”

As shown in FIG. 1, the semiconductor device 10 includes a semiconductor element 20, a lead frame 30, and the encapsulation resin 60. The package type of the semiconductor device 10 is small outline (SO) and is a small outline package (SOP) in the first embodiment. The package type of the semiconductor device 10 may be changed in any manner. The package type is not limited to SOP, and may be a quad flat non lead package (QFN), a dual flat package (DFP), a dual inline package (DIP), a quad flat package (QFP), a single inline package (SIP), a small outline J-leaded package (SOJ), or any other similar package type.

The semiconductor element 20 is a central element for the functions of the semiconductor device 10. In an example, the semiconductor element 20 includes a metal oxide semiconductor field effect transistor (power MOSFET) or an insulated gate bipolar transistor (IGBT). In the first embodiment, the semiconductor element 20 is a silicon carbide (SiC) MOSFET as a power MOSFET. Alternatively, the semiconductor element 20 may be a silicon (Si) MOSFET. The semiconductor element 20 has the form of a rectangular plate having a thickness in the Z-direction. Therefore, the Z-direction refers to the thickness direction of the semiconductor element 20. In an example, the semiconductor element 20 is rectangular in plan view so that the long sides extend in the X-direction and the short sides extend in the Y-direction.

The semiconductor element 20 includes an element head surface 20S and an element back surface 20R facing in opposite directions in the Z-direction. The semiconductor element 20 further includes first to fourth element side surfaces 20A to 20D joining the element head surface 20S to the element back surface 20R. The first element side surface 20A and the second element side surface 20B define opposite end surfaces of the semiconductor element 20 in the X-direction. The third element side surface 20C and the fourth element side surface 20D define opposite end surfaces of the semiconductor element 20 in the Y-direction.

The semiconductor element 20 includes multiple (in the first embodiment, twenty) power pads 21 and multiple (in the first embodiment, four) control pads 22 formed on the element head surface 20S. The power pads 21 and the control pads 22 are arranged on a peripheral portion of the element head surface 20S. Details of the power pads 21 and the control pads 22 will be described later.

As shown in FIG. 4, the semiconductor element 20 includes a source electrode 23 formed on the element head surface 20S and a drain electrode 24 formed on the element back surface 20R. The structure of the source electrode 23 will be described later. The drain electrode 24 is formed on the entirety of the element back surface 20R. The source electrode 23 is an example of a “surface electrode.”

As shown in FIG. 2, the lead frame 30 includes a die pad 31 supporting the semiconductor element 20 and multiple leads 32A to 32D and 33A to 33D arranged around the die pad 31. In the description hereinafter, the leads 32A to 32D refer to “first to fourth power leads 32A to 32D.” The leads 33A to 33D refer to “first to fourth control leads 33A to 33D.” The first to fourth power leads 32A to 32D and the first to fourth control leads 33A to 33D are external terminals of the semiconductor device 10. In the present disclosure, the first to fourth power leads 32A to 32D are examples of “multiple leads.” The first power lead 32A is an example of a “first lead.” The second power lead 32B is an example of a “second lead.” The third power lead 32C is an example of a “third lead.” The fourth power lead 32D is an example of a “fourth lead.”

The die pad 31 has the form of a rectangular plate having a thickness in the Z-direction. The die pad 31 is rectangular in plan view so that the long sides extend in the X-direction and the short sides extend in the Y-direction. The die pad 31 includes a die pad head surface 31S and a die pad back surface 31R facing in opposite directions in the Z-direction. The die pad 31 further includes four die pad side surfaces joining the die pad head surface 31S to the die pad back surface 31R, namely first to fourth die pad side surfaces 31A to 31D. The first die pad side surface 31A and the second die pad side surface 31B define opposite end surfaces of the die pad 31 in the X-direction. The third die pad side surface 31C and the fourth die pad side surface 31D define opposite end surfaces of the die pad 31 in the Y-direction.

As shown in FIG. 4, the semiconductor element 20 is arranged on the die pad 31 so that the drain electrode 24 faces the die pad head surface 31S. The semiconductor element 20 is bonded to the die pad head surface 31S by a conductive bonding material SD. Thus, the drain electrode 24 is electrically connected to the die pad 31. The conductive bonding material SD may be, for example, solder paste or silver paste.

In plan view, the first to fourth power leads 32A to 32D are offset from the center, in the Y-direction, of the die pad 31 toward the third die pad side surface 31C. The first power lead 32A and the second power lead 32B are arranged to face the third die pad side surface 31C in the Y-direction. The first power lead 32A and the second power lead 32B are arranged next to each other in the X-direction. The third power lead 32C is offset from the first power lead 32A and the second power lead 32B toward the first die pad side surface 31A. The third power lead 32C faces a corner of the die pad 31 formed by the first die pad side surface 31A and the third die pad side surface 31C. The fourth power lead 32D is offset from the first power lead 32A and the second power lead 32B toward the second die pad side surface 31B. The fourth power lead 32D faces a corner of the die pad 31 formed by the second die pad side surface 31B and the third die pad side surface 31C.

Each of the first to fourth power leads 32A to 32D includes a wire pad 32P and a lead portion 32Q. In an example, the wire pad 32P is integrated with the lead portion 32Q. In an example, the first power lead 32A and the second power lead 32B are identical in shape. In an example, the third power lead 32C and the fourth power lead 32D are symmetrical in shape. In each of the first power lead 32A and the second power lead 32B, the wire pad 32P is rectangular so that the long sides extend in the X-direction and the short sides extend in the Y-direction. The wire pad 32P of the third power lead 32C is L-shaped to surround the first die pad side surface 31A and the third die pad side surface 31C in plan view. The wire pad 32P of the fourth power lead 32D is L-shaped to surround the second die pad side surface 31B and the third die pad side surface 31C in plan view.

In each of the first to fourth power leads 32A to 32D, the lead portion 32Q extends in the Y-direction in plan view. A portion of the lead portion 32Q projects from the encapsulation resin 60 to the exterior and is used as an external terminal.

In plan view, the first to fourth control leads 33A to 33D are offset from the center, in the Y-direction, of the die pad 31 toward the fourth die pad side surface 31D. The first control lead 33A and the second control lead 33B are arranged to face the fourth die pad side surface 31D in the Y-direction. The first control lead 33A and the second control lead 33B are arranged next to each other in the X-direction. In an example, the first control lead 33A and the second control lead 33B are identical in shape to the first power lead 32A and the second power lead 32B. The third control lead 33C is offset from the first control lead 33A and the second control lead 33B toward the first die pad side surface 31A. The third control lead 33C faces a corner of the die pad 31 formed by the first die pad side surface 31A and the fourth die pad side surface 31D. In an example, the third control lead 33C and the fourth power lead 32D are identical in shape. The fourth control lead 33D is offset from the first control lead 33A and the second control lead 33B toward the second die pad side surface 31B. The fourth control lead 33D faces a corner of the die pad 31 formed by the second die pad side surface 31B and the fourth die pad side surface 31D. In an example, the fourth control lead 33D and the third power lead 32C are identical in shape. Each of the first to fourth control leads 33A to 33D includes a wire pad 33P and a lead portion 33Q in the same manner as the first to fourth power leads 32A to 32D. In each of the first to fourth control leads 33A to 33D, a portion of the lead portion 33Q projects from the encapsulation resin 60 to the exterior and is used as an external terminal.

In the semiconductor element 20, the power pads 21 and the first to fourth power leads 32A to 32D are separately electrically connected by first to fourth wires 71 to 74. The control pads 22 and the first to fourth control leads 33A to 33D are separately electrically connected by fifth to eighth wires 75 to 78.

As shown in FIG. 2, the encapsulation resin 60 encapsulates the semiconductor element 20, the first to eighth wires 71 to 78, and a portion of the lead frame 30. The encapsulation resin 60 is formed from an insulating material. The insulating material is, for example, a black epoxy resin.

The encapsulation resin 60 has the form of a rectangular plate having a thickness in the Z-direction. The encapsulation resin 60 includes an encapsulation head surface 61 and an encapsulation back surface 62 facing opposite directions in the Z-direction. The encapsulation resin 60 further includes first to fourth encapsulation side surfaces 63 to 66, which are four encapsulation side surfaces joining the encapsulation head surface 61 to the encapsulation back surface 62. The first encapsulation side surface 63 and the second encapsulation side surface 64 define opposite end surfaces of the encapsulation resin 60 in the X-direction. The third encapsulation side surface 65 and the fourth encapsulation side surface 66 define opposite end surfaces of the encapsulation resin 60 in the Y-direction. As shown in FIG. 3, the encapsulation head surface 61 and the die pad head surface 31S face in the same direction. The encapsulation back surface 62 and the die pad back surface 31R face in the same direction. Therefore, the encapsulation head surface 61 and the element head surface 20S of the semiconductor element 20 face in the same direction. The encapsulation back surface 62 and the element back surface 20R face in the same direction. As shown in FIGS. 3 and 4, the die pad back surface 31R is exposed from the encapsulation back surface 62. The die pad back surface 31R is used as a drain terminal as an external terminal of the semiconductor device 10. As shown in FIG. 2, the first encapsulation side surface 63 and the first die pad side surface 31A face in the same direction. The second encapsulation side surface 64 and the second die pad side surface 31B face in the same direction. The third encapsulation side surface 65 and the third die pad side surface 31C face in the same direction. The fourth encapsulation side surface 66 and the fourth die pad side surface 31D face in the same direction.

In each of the first to fourth power leads 32A to 32D, the lead portion 32Q projects from the third encapsulation side surface 65 to the exterior of the encapsulation resin 60. In each of the first to fourth control leads 33A to 33D, the lead portion 33Q projects from the fourth encapsulation side surface 66 to the exterior of the encapsulation resin 60.

### Circuit Configuration of Semiconductor Device

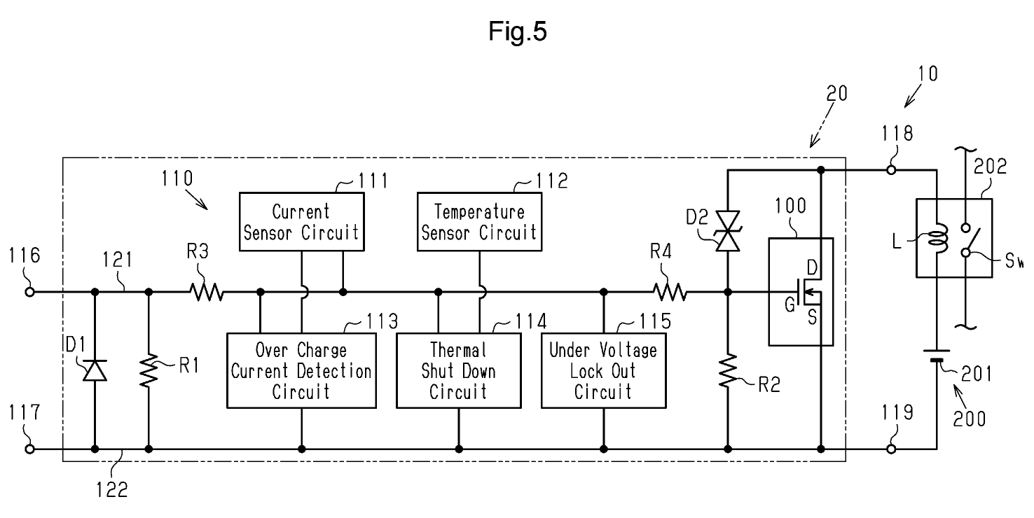

An example of a circuit configuration of the semiconductor device 10 will now be described with reference to FIG. 5.

As shown in FIG. 5, the semiconductor device 10 includes a switching circuit 100 including a power transistor (in the first embodiment, power MOSFET) and a control circuit 110 configured to control the switching circuit 100. The switching circuit 100 and the control circuit 110 are arranged on the semiconductor element 20. In an example, the control circuit 110 includes a current sensor circuit 111, a temperature sensor circuit 112, an over charge current detection (OCD) circuit 113, a thermal shut down (TSD) circuit 114, and an under voltage lock out (UVLO) circuit 115.

The semiconductor device 10 includes an input terminal 116, input-side ground terminal 117, an output terminal 118, and an output-side ground terminal 119. In an example, the input terminal 116 is formed of one of the first to fourth control leads 33A to 33D (refer to FIG. 2). In an example, the input-side ground terminal 117 is formed of another one of the first to fourth control leads 33A to 33D. The output terminal 118 is formed of the die pad 31(refer to FIG. 3). The output-side ground terminal 119 is formed of the first to fourth power leads 32A to 32D.

In the example shown in FIG. 5, a series circuit 200 including a power supply 201 and an inductive load 202 is electrically connected to the output terminal 118 and the output-side ground terminal 119. In the example shown in FIG. 5, the inductive load 202 is a relay including a switch Sw and a coil L.

The switching circuit 100 is electrically connected between the output terminal 118 and the output-side ground terminal 119. The switching circuit 100 includes a power MOSFET. The power MOSFET includes a gate terminal G, a drain terminal D, and a source terminal S. In the switching circuit 100, the drain terminal D is electrically connected to the output terminal 118, and the source terminal S is electrically connected to the output-side ground terminal 119.

The semiconductor device 10 includes an input line 121 connecting the input terminal 116 to the gate terminal G of the switching circuit 100 and a ground line 122 connecting the input-side ground terminal 117 to the output-side ground terminal 119. A diode D1, a first resistor R1, the over charge current detection circuit 113, the thermal shut down circuit 114, the under voltage lock out circuit 115, and a second resistor R2 are connected in parallel to one another between the input line 121 and the ground line 122 in order from the input terminal 116. A third resistor R3 is connected in series between the first resistor R1 and the over charge current detection circuit 113 in the input line 121. A fourth resistor R4 is connected in series between the under voltage lock out circuit 115 and the second resistor R2 in the input line 121.

The current sensor circuit 111 is electrically connected to the over charge current detection circuit 113. The current sensor circuit 111 is, for example, configured to detect current flowing through the input line 121. A current value detected by the current sensor circuit 111 is transmitted to the over charge current detection circuit 113. The over charge current detection circuit 113 is driven in accordance with the current value received from the current sensor circuit 111. In an example, when a current (overcurrent) of a predetermined value or greater flows to the input line 121 due to a short circuit or static electricity, the over charge current detection circuit 113 is configured to send the overcurrent from the input line 121 toward the ground line 122 to protect other circuits from the overcurrent.

The temperature sensor circuit 112 is electrically connected to the thermal shut down circuit 114. The temperature sensor circuit 112 is configured to detect the temperature of the semiconductor element 20. The temperature detected by the temperature sensor circuit 112 is output to the thermal shut down circuit 114. The thermal shut down circuit 114 is driven in accordance with the temperature detected by the temperature sensor circuit 112. In an example, when the temperature of the semiconductor element 20 becomes greater than or equal to a predetermined temperature, the thermal shut down circuit 114 is configured to prohibit the supply of power to the input line 121. This limits increases in the temperature of the semiconductor element 20.

The under voltage lock out circuit 115 is configured to prohibit actuation of the switching circuit 100 when the potential difference between the input line 121 and the ground line 122 is less than a predetermined value and permit actuation of the switching circuit 100 when the potential difference is greater than or equal to a predetermined value.

In the switching circuit 100, a clamp diode D2 is electrically connected between the gate terminal G and the drain terminal D. The clamp diode D2 is formed of two diodes connected in reverse bias. The diodes may include, for example, a Zener diode. The clamp diode D2 has a breakdown voltage V2 that is lower than a breakdown voltage V1 between the drain terminal D and the source terminal S of the power MOSFET. Therefore, when the breakdown voltage V1 is applied between the drain terminal D and the source terminal S, the clamp diode D2 is configured to undergo breakdown before the switching circuit 100.

When the inductive load 202 is switched off and a counter-electromotive force V3 generated in the coil L is greater than the breakdown voltage V1 between the drain terminal D and the source terminal S, breakdown of the clamp diode D2 occurs. The breakdown of the clamp diode D2 causes current to flow to the second resistor R2. This generates voltage (gate voltage) between the gate terminal G and the source terminal S. The gate voltage switches on the switching circuit 100 (power MOSFET). As a result, current generated by the counter-electromotive force V3 flows between the drain terminal D and the source terminal S.

As described above, the clamp diode D2 reduces loads on the switching circuit 100, and the switching circuit 100 absorbs the energy accumulated in the inductive load 202. The amount of energy absorbed from the inductive load 202 is expressed by dynamic clamp energy capability Eac, which is one of the characteristics of the power MOSFET. As the value of the dynamic clamp energy capability Eac increases, a greater amount of energy is absorbed from the inductive load 202. The configuration of the control circuit 110 may be changed in any manner.

### Structure of Semiconductor Element

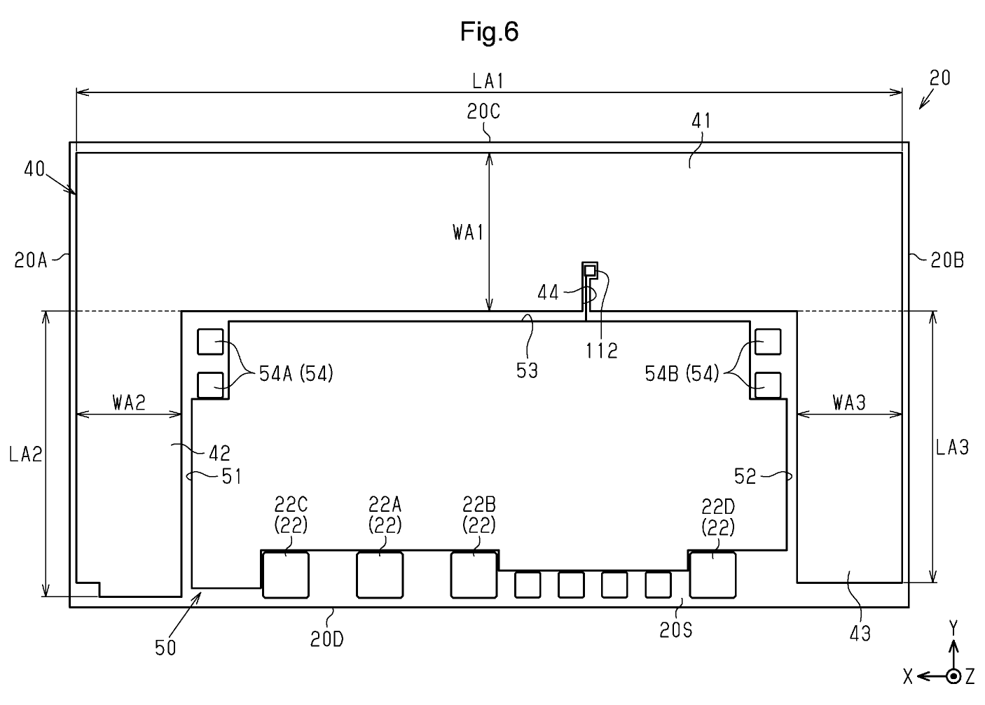

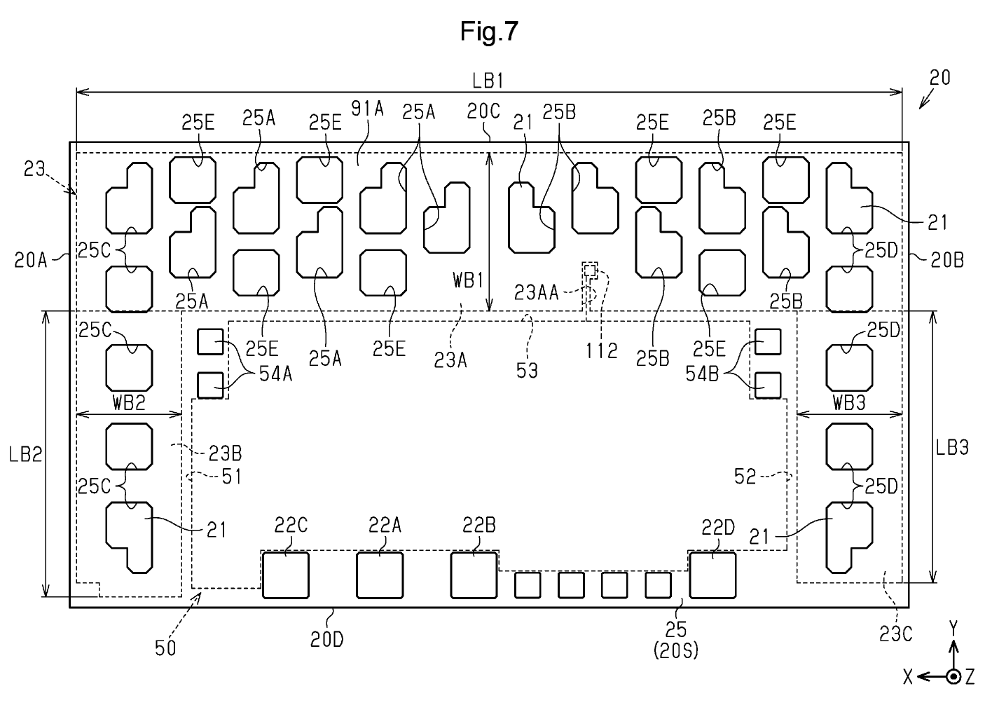

With reference to FIGS. 6 and 7, the schematic inner structure of the semiconductor element 20 will now be described.

FIG. 6 is a schematic plan view of the internal structure of the semiconductor element 20. FIG. 7 is a schematic plan view of the semiconductor element 20 shown in FIG. 6, additionally showing the source electrode 23 and a passivation film 25, which will be described later.

The element head surface 20S of the semiconductor element 20 includes an active region 40 in which a power transistor (in the first embodiment, power MOSFET) is formed and a control circuit region 50 in which the control circuit 110 is formed. In other words, the switching circuit 100 shown in FIG. 5 is formed in the active region 40.

The control circuit region 50 is arranged at the center in the X-direction and toward the fourth element side surface 20D in the Y-direction. In plan view, the control circuit region 50 is rectangular so that the long sides extend in the X-direction and the short sides extend in the Y-direction. In plan view, the control circuit region 50 includes a first side 51 located close to the first element side surface 20A, a second side 52 located close to the second element side surface 20B, and a third side 53 located close to the third element side surface 20C. The first side 51 and the second side 52 each have a portion extending in the Y-direction. The third side 53 has a portion extending in the X-direction. The third side 53 is offset from the center, in the Y-direction, of the element head surface 20S of the semiconductor element 20 toward the third element side surface 20C. The dimension of the control circuit region 50 in the X-direction is larger than or equal to 1/2 of the dimension of the element head surface 20S in the X-direction. In an example, the dimension of the control circuit region 50 in the X-direction is larger than or equal to 2/3 of the dimension of the element head surface 20S in the X-direction. In an example, the dimension of the control circuit region 50 in the X-direction is approximately 3/4.

The dimension of the control circuit region 50 in the X-direction is defined by the distance between the first side 51 and the second side 52 in the X-direction. The dimension of the element head surface 20S in the X-direction is defined by the distance between the first element side surface 20A and the second element side surface 20B in the X-direction.

As shown in FIG. 6, the semiconductor element 20 may include multiple inner pads 54. The inner pads 54 includes two first inner pads 54A and two second inner pads 54B, which are located at different positions. The first inner pads 54A are arranged at a corner of the control circuit region 50 formed by the first side 51 and the third side 53. In plan view, the control circuit region 50 is recessed so as to avoid the first inner pads 54A. The first inner pads 54A are arranged next to each other in the Y-direction. The second inner pads 54B are arranged at a corner of the control circuit region 50 formed by the second side 52 and the third side 53. In plan view, the control circuit region 50 is recessed so as to avoid the second inner pads 54B. The second inner pads 54B are arranged next to each other in the Y-direction. In an example, the second side 52 is shorter than the first side 51 in the Y-direction. The length of each of the first side 51 and the second side 52 in the Y-direction may be changed in any manner.

The inner pads 54 may include an inner pad connected to the gate terminal G of the switching circuit 100. The inner pads 54 may include an inner pad connected to the control circuit 110. The inner pads 54 may differ in the size in plan view from the power pads 21 and/or the control pads 22. In an example, the inner pads 54 may be smaller in plan view than the power pads 21 and the control pads 22.

Multiple (in the first embodiment, four) control pads 22 are arranged between the control circuit region 50 and the fourth element side surface 20D in the Y-direction. The control pads 22 are located at the same position in the Y-direction and separated from each other in the X-direction. Hereinafter, the four control pads 22 are referred to as “control pads 22A to 22D.”

The control pads 22A and 22B are arranged between the control pad 22C and the control pad 22D in the X-direction. The control pad 22A is offset from the control pad 22B toward the first element side surface 20A. The control pad 22C is offset from the control pads 22A and 22B toward the first element side surface 20A. The control pad 22D is offset from the control pads 22A and 22B toward the second element side surface 20B.

The control pad 22A is electrically connected to the first control lead 33A by the fifth wire 75 (refer to FIG. 2). The control pad 22B is electrically connected to the second control lead 33B by the sixth wire 76 (refer to FIG. 2). The control pad 22C is electrically connected to the third control lead 33C by the seventh wire 77 (refer to FIG. 2). The control pad 22D is electrically connected to the fourth control lead 33D by the eighth wire 78 (refer to FIG. 2). The fifth to eighth wires 75 to 78 are formed from, for example, a metal material such as copper (Cu), aluminum (Al), gold (Au), or Ag. In the first embodiment, the fifth to eighth wires 75 to 78 are formed from a material including Cu.

In plan view, the active region 40 surrounds the control circuit region 50 from opposite sides in the X-direction and from one side in the Y-direction. In plan view, the active region 40 is located adjacent to the control circuit region 50. In an example, the active region 40 may be divided into a first transistor region 41 offset from the control circuit region 50 toward the third element side surface 20C, a second transistor region 42 located adjacent to the first side 51 of the control circuit region 50 in the X-direction, and a third transistor region 43 located adjacent to the second side 52 in the X-direction. The broken lines shown in the active region 40 indicate the boundary between the first transistor region 41 and the second transistor region 42 and the boundary between the first transistor region 41 and the third transistor region 43.

The active region 40 surrounds the control circuit region 50 from opposite sides in the X-direction with the second transistor region 42 and the third transistor region 43. The active region 40 surrounds the control circuit region 50 from one side in the Y-direction (side of the third element side surface 20C) with the first transistor region 41.

In plan view, the second transistor region 42 is rectangular so that the long sides extend in the Y-direction and the short sides extend in the X-direction. In plan view, the second transistor region 42 has a distal edge located adjacent to the fourth element side surface 20D in the Y-direction. Therefore, the second transistor region 42 is formed adjacent, in the X-direction, to the entirety of the first side 51 of the control circuit region 50 in the Y-direction. In an example, the second transistor region 42 has a width dimension WA2 (dimension in the X-direction) that is approximately 1/8 of the dimension of the element head surface 20S in the X-direction. The first transistor region 41 has a width dimension WA1 (dimension in the Y-direction). The second transistor region 42 has a length dimension LA2 (dimension in the Y-direction) that is larger than the width dimension WA1.

In plan view, the third transistor region 43 is rectangular so that the long sides extend in the Y-direction and the short sides extend in the X-direction. In an example, the third transistor region 43 has a width dimension WA3 (dimension in the X-direction) that is approximately 1/8 of the dimension of the element head surface 20S in the X-direction. Therefore, the width dimension WA3 of the third transistor region 43 may be equal to the width dimension WA2 of the second transistor region 42. The third transistor region 43 has a length dimension LA3 (dimension in the Y-direction) that is larger than the width dimension WA1 of the first transistor region 41. In an example, the length dimension LA3 of the third transistor region 43 is smaller than the length dimension LA2 of the second transistor region 42. Therefore, the third transistor region 43 has a distal edge located closer, in the Y-direction, to the first transistor region 41 than the distal edge of the second transistor region 42 is. The third transistor region 43 is formed adjacent, in the X-direction, to the entirety of the second side 52 of the control circuit region 50 in the Y-direction. The length dimension LA3 of the third transistor region 43 may be equal to the length dimension LA2 of the second transistor region 42.

The first transistor region 41 includes a region located adjacent to the third side 53 of the control circuit region 50 in the Y-direction. The first transistor region 41 is rectangular in plan view so that the long sides extend in the X-direction and the short sides extend in the Y-direction. The first transistor region 41 has a length direction LA1 (dimension in the X-direction) that is larger than the dimension of the control circuit region 50 in the X-direction. In an example, the width dimension WA1 of the first transistor region 41 is smaller than twice the width dimension WA2 of the second transistor region 42. In an example, the width dimension WA1 of the first transistor region 41 is smaller than twice the width dimension WA3 of the third transistor region 43. In an example, the width dimension WA1 of the first transistor region 41 is approximately 1.5 times the width dimension WA2 (WA3) of the second transistor region 42 (the third transistor region 43).

In an example, the first transistor region 41 includes a slit 44 to avoid the temperature sensor circuit 112. The slit 44 is offset from the center, in the X-direction, of the first transistor region 41 toward the third transistor region 43.

As shown in FIG. 7, the source electrode 23 is formed on the active region 40 (refer to FIG. 6). Although not shown, the source electrode 23 is formed on an insulation layer that covers the power MOSFET formed in the active region 40. The source electrode 23 is electrically connected to the power MOSFET in the active region 40 by connection lines that extend through the insulation layer in the Z-direction. Thus, the source electrode 23 is arranged on the active region 40 at a position different from the control circuit region 50.

In the example shown in FIG. 7, in plan view, the source electrode 23 is identical to the active region 40 in shape. More specifically, as shown in FIGS. 6 and 7, the source electrode 23 includes a first electrode region 23A corresponding to the first transistor region 41, a second electrode region 23B corresponding to the second transistor region 42, and a third electrode region 23C corresponding to the third transistor region 43. Therefore, in plan view, the source electrode 23 surrounds the control circuit region 50 from opposite sides in the X-direction and from one side in the Y-direction. In plan view, the first electrode region 23A is located adjacent to the control circuit region 50 in the Y-direction. The second electrode region 23B is located between the control circuit region 50 and the first element side surface 20A. The third electrode region 23C is located between the control circuit region 50 and the second element side surface 20B. In plan view, the second electrode region 23B and the third electrode region 23C are separately arranged at opposite sides of the control circuit region 50 in the X-direction.

The first electrode region 23A covers the first transistor region 41. Therefore, the first electrode region 23A includes a region located adjacent to the third side 53 of the control circuit region 50 in the Y-direction. The first electrode region 23A is rectangular in plan view so that the long sides extend in the X-direction and the short sides extend in the Y-direction. The first electrode region 23A has a length direction LB1 (dimension in the X-direction) that is larger than the dimension of the control circuit region 50 in the X-direction. The first electrode region 23A has a width dimension WB1 (dimension in the Y-direction). The second electrode region 23B has a width dimension WB2 (dimension in the Y-direction). In an example, the width dimension WB1 is smaller than twice the width dimension WB2. The third electrode region 23C has a width dimension WB3 (dimension in the Y-direction). In an example, the width dimension WB1 of the first electrode region 23A is smaller than twice the width dimension WB3. In an example, the width dimension WB1 of the first electrode region 23A is approximately 1.5 times the width dimension WB2 (WB3) of the second electrode region 23B (the third electrode region 23C).

In an example, the first electrode region 23A includes a slit 23AA to avoid the temperature sensor circuit 112. The slit 23AA is offset from the center, in the X-direction, of the first electrode region 23A toward the third electrode region 23C. In plan view, the slit 23AA overlaps the slit 44 of the first transistor region 41. Therefore, in plan view, the temperature sensor circuit 112 is exposed from the source electrode 23.

The second electrode region 23B covers the second transistor region 42. Therefore, in plan view, the second electrode region 23B is located adjacent to the first side 51 of the control circuit region 50 in the X-direction. The second electrode region 23B is rectangular in plan view so that the long sides extend in the Y-direction and the short sides extend in the X-direction. In plan view, the second electrode region 23B has a distal edge located adjacent to the fourth element side surface 20D in the Y-direction. Therefore, the second electrode region 23B is formed adjacent, in the X-direction, to the entirety of the first side 51 of the control circuit region 50 in the Y-direction. In an example, the width dimension WB2 (dimension in the X-direction) of the second electrode region 23B is approximately 1/8 of the dimension of the element head surface 20S in the X-direction. The second electrode region 23B has a length dimension LB2 (dimension in the Y-direction) that is larger than the width dimension WB1 of the first electrode region 23A.

The third electrode region 23C covers the third transistor region 43. Therefore, in plan view, the third electrode region 23C is located adjacent to the second side 52 of the control circuit region 50 in the X-direction. The third electrode region 23C is rectangular in plan view so that the long sides extend in the Y-direction and the short sides extend in the X-direction. In an example, the width dimension WB3 of the third electrode region 23C is approximately 1/8 of the dimension of the element head surface 20S in the X-direction. That is, the width dimension WB3 of the third electrode region 23C may be equal to the width dimension WB2 of the second electrode region 23B. The third electrode region 23C has a length dimension LB3 (dimension in the Y-direction) that is larger than the width dimension WB1 of the first electrode region 23A. In an example, the length dimension LB3 of the third electrode region 23C is smaller than the length dimension LB2 of the second electrode region 23B. Therefore, the third electrode region 23C has a distal edge located closer, in the Y-direction, to the first electrode region 23A than the distal edge of the second electrode region 23B is. The third electrode region 23C is formed adjacent, in the X-direction, to the entirety of the second side 52 of the control circuit region 50 in the Y-direction. The length dimension LB3 of the third electrode region 23C may be equal to the length dimension LB2 of the second electrode region 23B.

The source electrode 23 and the control circuit region 50 are, for example, covered by the passivation film 25. The passivation film 25 is a protective film protecting the semiconductor element 20 and is formed of, for example, silicon nitride (SiN) or silicon oxide (SiO₂).

The passivation film 25 includes multiple first to fifth openings 25A to 25E over the source electrode 23. The source electrode 23 includes portions exposed in the first to fifth openings 25A to 25E, defining the power pads 21. The power pads 21 exposed in the first to fourth openings 25A to 25D are source pads to which the first to fourth wires 71 to 74 are connected.

The first openings 25A and the second openings 25B are arranged in a portion of the passivation film 25 covering the first electrode region 23A.

The first openings 25A (in the first embodiment, five) are offset from the center, in the X-direction, of the first electrode region 23A toward the second electrode region 23B in plan view. The first openings 25A are separated from each other in the X-direction. Of the first openings 25A, the first openings 25A adjacent to each other in the X-direction are offset from each other in the Y-direction.

The second openings 25B (in the first embodiment, five) are offset from the center, in the X-direction, of the first electrode region 23A toward the third electrode region 23C in plan view. The second openings 25B are separated from each other in the X-direction. Of the second openings 25B, the second openings 25B adjacent to each other in the X-direction are offset from each other in the Y-direction. In an example, the arrangement of the second openings 25B is symmetrical to the arrangement of the first openings 25A about an imaginary line extending in the Y-direction through the center, in the X-direction, of the first electrode region 23A.

The third openings 25C are arranged in a portion of the passivation film 25 covering the first electrode region 23A and a portion of the passivation film 25 covering the second electrode region 23B. The third openings 25C are located at the same position in the X-direction and are separated from each other in the Y-direction. The third openings 25C are offset from the first openings 25A toward the first element side surface 20A.

The fourth openings 25D are arranged in a portion of the passivation film 25 covering the first electrode region 23A and a portion of the passivation film 25 covering the third electrode region 23C. The fourth openings 25D are located at the same position in the X-direction and are separated from each other in the Y-direction. The fourth openings 25D are offset from the second openings 25B toward the second element side surface 20B.

The fifth openings 25E are arranged in a portion of the passivation film 25 covering the first electrode region 23A. The fifth openings 25E are arranged adjacent to the first openings 25A in the Y-direction. Also, the fifth openings 25E are arranged adjacent to the second openings 25B in the Y-direction.

### Connection Structure of Semiconductor Element with Wires

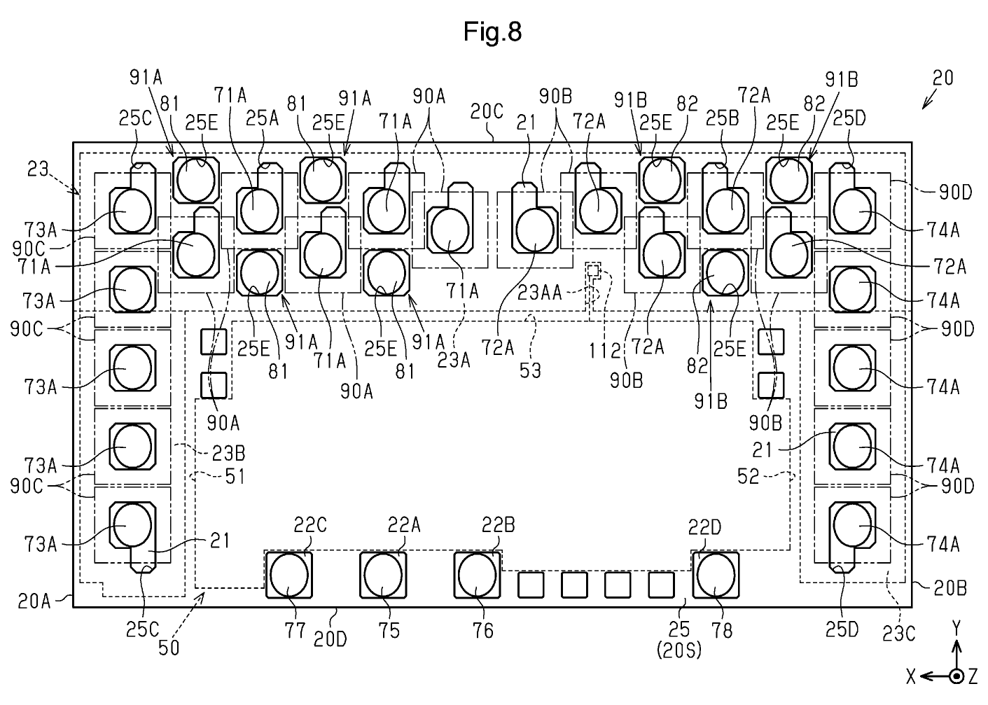

With reference to FIGS. 8 to 10, the connection structure of the semiconductor element 20 with the first to fourth wires 71 to 74 will be described.

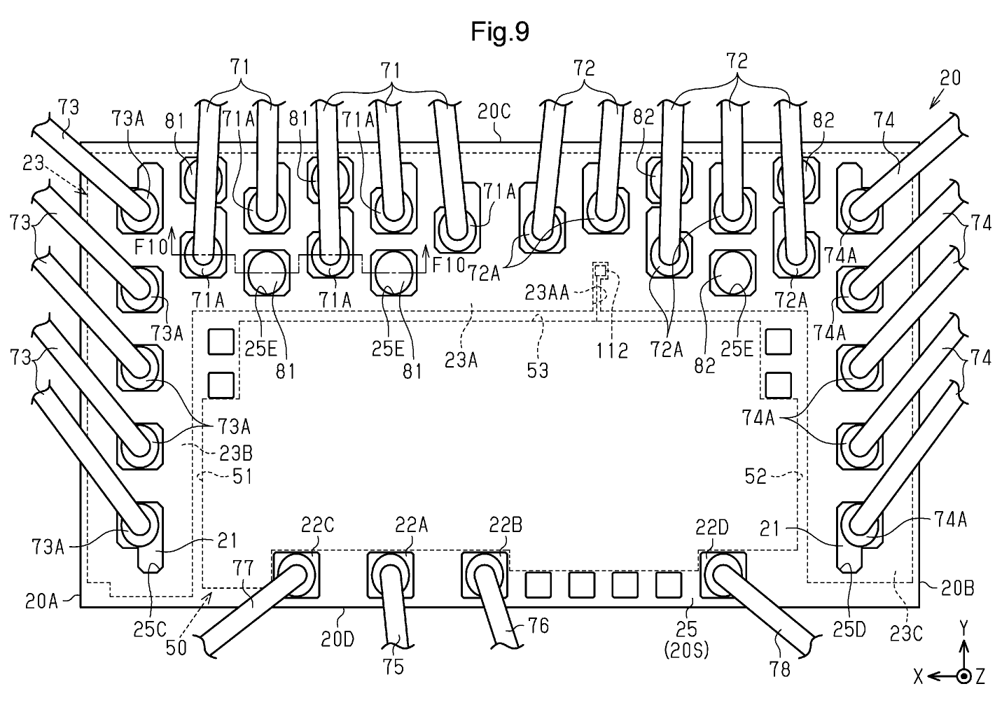

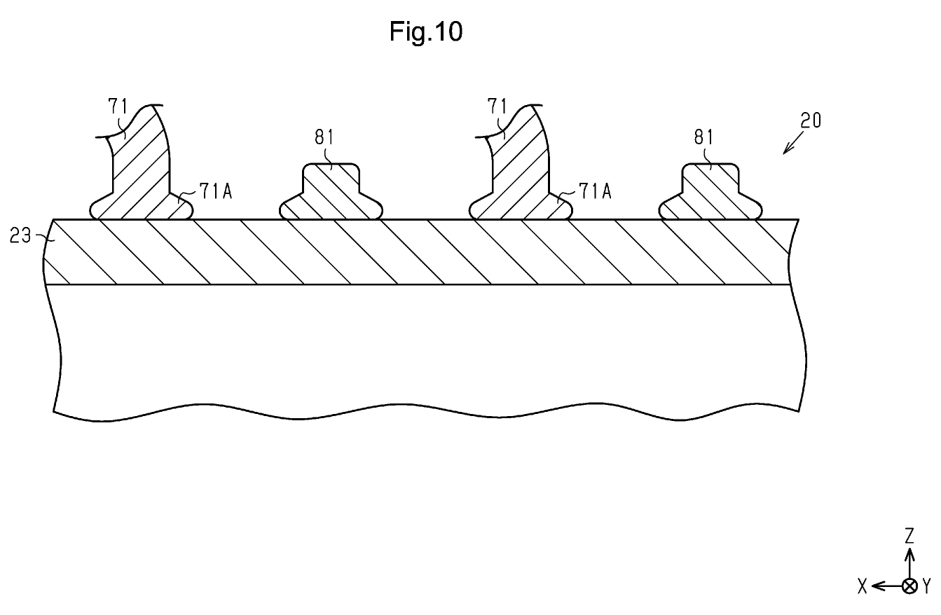

FIG. 8 is a schematic plan view of the semiconductor element 20 shown in FIG. 7, additionally showing first to fourth electrode connectors 71A to 74A of the first to fourth wires 71 to 74 and heat dissipation regions 90A to 90B (rectangles indicated by double-dashed lines) where heat is dissipated via the first to fourth wires 71 to 74. FIG. 9 is a schematic plan view of the semiconductor element 20 shown in FIG. 8, additionally showing the first to fourth wires 71 to 74. FIG. 10 is a schematic cross-sectional view of the first wires 71 and first heat dissipation elements 81, which will be described later. FIG. 9 does not show the heat dissipation regions 90A to 90D to facilitate understanding of the drawing.

As shown in FIGS. 8 and 9, the first wires 71 are separately connected to the power pads 21(source pads) exposed from the first openings 25A. Each first wire 71 includes a first electrode connector 71A. The first wire 71 is a bonding wire formed using a wire bonder. The first electrode connector 71A of the first wire 71 includes a first bonding portion. In other words, the first electrode connector 71A includes a ball bond.

The first electrode connectors 71A are separated from each other in the X-direction. Adjacent ones of the first electrode connectors 71A in the X-direction are offset from each other in the Y-direction. More specifically, the first electrode connectors 71A include a first electrode connector 71A offset from the center, in the Y-direction, of the first electrode region 23A toward the control circuit region 50 and a first electrode connector 71A offset from the center, in the Y-direction, of the first electrode region 23A toward the third element side surface 20C. The first electrode connector 71A located closest to the second element side surface 20B among the first electrode connectors 71A is arranged in the center, in the Y-direction, of the first electrode region 23A.

The second wires 72 are separately connected to the power pads 21 (source pads) exposed from the second openings 25B. Each second wire 72 includes a second electrode connector 72A. The second electrode connector 72A includes a ball bond in the same manner as the first electrode connector 71A of the first wire 71.

The second electrode connectors 72A are separated from each other in the X-direction. Adjacent ones of the second electrode connectors 72A in the X-direction are offset from each other in the Y-direction. More specifically, the second electrode connectors 72A include a second electrode connector 72A offset from the center, in the Y-direction, of the first electrode region 23A toward the control circuit region 50 and a second electrode connector 72A offset from the center, in the Y-direction, of the first electrode region 23A toward the third element side surface 20C. The second electrode connector 72A located closest to the first element side surface 20A among the second electrode connectors 72A is arranged in the center, in the Y-direction, of the first electrode region 23A.

The third wires 73 are separately connected to the power pads 21 (source pads) exposed from the third openings 25C. Each third wire 73 includes a third electrode connector 73A. The third electrode connector 73A includes a ball bond in the same manner as the first electrode connector 71A of the first wire 71.

The third electrode connectors 73A are located at the same position in the X-direction and are separated from each other in the Y-direction. Of the third electrode connectors 73A, three third electrode connectors 73A are arranged in the second electrode region 23B, and the remaining two third electrode connectors 73A are arranged in the first electrode region 23A. The two third electrode connectors 73A are arranged at one of opposite ends, in the X-direction, of the first electrode region 23A located closer to the first element side surface 20A.

The fourth wires 74 are separately connected to the power pads 21 (source pads) exposed from the fourth openings 25D. Each fourth wire 74 includes a fourth electrode connector 74A. The fourth electrode connector 74A includes a ball bond in the same manner as the first electrode connector 71A of the first wire 71.

The fourth electrode connectors 74A are located at the same position in the X-direction and are separated from each other in the Y-direction. Of the fourth electrode connectors 74A, three fourth electrode connectors 74A are arranged in the third electrode region 23C, and the remaining two fourth electrode connectors 74A are arranged in the first electrode region 23A. The two fourth electrode connectors 74A are arranged at one of opposite ends, in the X-direction, of the first electrode region 23A located closer to the second element side surface 20B.

The first to fourth wires 71 to 74 are, for example, formed from a metal material such as Cu, Al, Au, or Ag. In the first embodiment, the first to fourth wires 71 to 74 are formed from a material including Cu. The first to fourth wires 71 to 74 may be, for example, formed from the same material as the fifth to eighth wires 75 to 78.

As shown in FIG. 8, the heat dissipation regions 90A to 90D indicated by double-dashed lines indicate regions where heat is dissipated from the source electrode 23 via the first to fourth wires 71 to 74. Each of the heat dissipation regions 90A to 90D of the first to fourth wires 71 to 74 has the form of, for example, a rectangle centered on corresponding first to fourth electrode connectors 71A to 74A. In an example, the heat dissipation regions 90A to 90D are identical in size.

Heat dissipation regions 90A corresponding to the first wires 71 are arranged so as to surround each first electrode connector 71A in plan view. Adjacent ones of the heat dissipation regions 90A in the X-direction partially overlap each other.

Heat dissipation regions 90B corresponding to the second wires 72 are arranged so as to surround each second electrode connector 72A in plan view. Adjacent ones of the heat dissipation regions 90B in the X-direction partially overlap each other.

Heat dissipation regions 90C corresponding to the third wires 73 are arranged so as to surround each third electrode connector 73A in plan view. Therefore, the heat dissipation regions 90C are arranged next to one another in the Y-direction. Of the heat dissipation regions 90C, two heat dissipation regions 90C corresponding to the first electrode region 23A partially overlap with the heat dissipation region 90A that is closest to the first element side surface 20A among the heat dissipation regions 90A.

Heat dissipation regions 90D corresponding to the fourth wires 74 are arranged so as to surround each fourth electrode connector 74A in plan view. Therefore, the heat dissipation regions 90D are arranged next to one another in the Y-direction. Of the heat dissipation regions 90D, two heat dissipation regions 90D corresponding to the first electrode region 23A partially overlap with the heat dissipation region 90B that is closest to the second element side surface 20B among the heat dissipation regions 90B.

The dimension of each heat dissipation region 90C in the X-direction is slightly smaller than the dimension of the second electrode region 23B in the X-direction. Three heat dissipation regions 90C are formed over most of the second electrode region 23B. Thus, heat dissipation from the second electrode region 23B is facilitated by the three heat dissipation regions 90C. Also, the dimension of each heat dissipation region 90D in the X-direction is slightly smaller than the dimension of the third electrode region 23C in the X-direction. Three heat dissipation regions 90D are formed over most of the third electrode region 23C. Thus, heat dissipation from the third electrode region 23C is facilitated by the three heat dissipation regions 90D.

In contrast, the width dimension WB1 (dimension in the Y-direction) of the first electrode region 23A is, for example, larger than the dimension of the heat dissipation region 90A in the Y-direction. In particular, in the example shown in FIG. 7, the width dimension WB1 of the first electrode region 23A is larger than or equal to twice the dimension of the heat dissipation region 90A in the Y-direction. Of the heat dissipation regions 90A, four heat dissipation regions 90A are offset from the center, in the Y-direction, of the first electrode region 23A in the Y-direction. Therefore, the first electrode region 23A includes a region (hereinafter, referred to as “non-heat dissipation region 91A”) that does not include the heat dissipation region 90A. In the non-heat dissipation region 91A, the temperature of the source electrode 23 increases more readily than in the heat dissipation region 90A. There are multiple (in the first embodiment, four) non-heat dissipation regions 91A. The non-heat dissipation regions 91A each have a fifth opening 25E. In other words, the non-heat dissipation regions 91A include the power pads 21 (source pads), which are the source electrode 23 exposed from the passivation film 25.

The first heat dissipation element 81 is arranged in each of the non-heat dissipation regions 91A. The first heat dissipation elements 81 are, for example, formed from the same material as the first to fourth wires 71 to 74. In the first embodiment, the first heat dissipation elements 81 are formed from a material including Cu. As shown in FIG. 10, the first heat dissipation elements 81 are identical to the first electrode connectors 71A in shape. More specifically, the first heat dissipation elements 81 are formed of ball bonds using a wire bonder.

As shown in FIG. 9, in plan view, each first heat dissipation element 81 is arranged with respect to the first electrode connector 71A in a direction in which the first wire 71 extends. Of the first heat dissipation elements 81, a first heat dissipation element 81 located adjacent to the first electrode connector 71A at a side close to the third element side surface 20C overlaps the first wire 71 in plan view. Of the first heat dissipation elements 81, a first heat dissipation element 81 located adjacent to the first electrode connector 71A at a side close to the fourth element side surface 20D is located where the first wire 71 cannot be formed to be connected to the first power lead 32A (refer to FIG. 2). As described above, since the first wire 71 cannot be formed in the non-heat dissipation region 91A, the first heat dissipation element 81 is formed, instead of the first wire 71, in the non-heat dissipation region 91A.

Of the heat dissipation regions 90B, four heat dissipation regions 90B are offset from the center, in the Y-direction, of the first electrode region 23A in the Y-direction. Therefore, the first electrode region 23A includes a region (hereinafter, referred to as “non-heat dissipation region 91B”) that does not include the heat dissipation region 90B. In the non-heat dissipation region 91B, the temperature of the source electrode 23 increases more readily than in the heat dissipation region 90B. There are multiple (in the first embodiment, four) non-heat dissipation regions 91B. The non-heat dissipation regions 91B each have a fifth opening 25E. In other words, the non-heat dissipation regions 91B include the power pads 21 (source pads), which are the source electrode 23 exposed from the passivation film 25.

The second heat dissipation element 82 is arranged in each of the non-heat dissipation regions 91B. The second heat dissipation elements 82 are, for example, formed from the same material as the first to fourth wires 71 to 74. In the first embodiment, the second heat dissipation elements 82 are formed from a material including Cu. Therefore, the second heat dissipation elements 82 is formed from the same material as the first heat dissipation elements 81. The second heat dissipation elements 82 are formed by ball bonding using a wire bonder in the same manner as the first heat dissipation elements 81. The second heat dissipation elements 82 are identical to the first heat dissipation elements 81 in shape. In other words, the second heat dissipation elements 82 are identical to the second electrode connectors 72A in shape.

As shown in FIG. 9, in plan view, each second heat dissipation element 82 is arranged with respect to the second electrode connector 72A in a direction in which the second wire 72 extends. Of the second heat dissipation elements 82, a second heat dissipation element 82 located adjacent to the second electrode connector 72A at a side close to the third element side surface 20C overlaps the second wire 72 in plan view. Of the second heat dissipation elements 82, a second heat dissipation element 82 located adjacent to the second electrode connector 72A at a side close to the fourth element side surface 20D is located where the second wire 72 cannot be formed to be connected to the second power lead 32B (refer to FIG. 2). As described above, since the second wire 72 cannot be formed in the non-heat dissipation region 91B, the second heat dissipation element 82 is formed, instead of the second wire 72, in the non-heat dissipation region 91B.

### Operation

The operation of the semiconductor device 10 in accordance with the first embodiment will now be described.

In accordance with the switching of the semiconductor device 10, heat is generated between the drain electrode 24 and the source electrode 23 due to the inductance of the inductive load. The heat is dissipated from the first electrode region 23A of the source electrode 23 to the control circuit region 50. The heat is dissipated from the second electrode region 23B to the control circuit region 50. The heat is dissipated from the third electrode region 23C to the control circuit region 50. That is, heat is transferred from the source electrode 23 to the control circuit region 50 through the three heat dissipation paths. This limits a local increase in temperature in the semiconductor element 20, thereby avoiding occurrence of avalanche breakdown. As a result, the avalanche withstand capability (active clamp energy capability) of the semiconductor device 10 is improved.

### Advantages

The semiconductor device 10 of the first embodiment has the advantages described below.

1-1 The semiconductor device 10 includes: the semiconductor element 20 including the element head surface 20S and the element back surface 20R facing in opposite directions, and the source electrode 23 formed on the element head surface 20S; the die pad 31 supporting the semiconductor element 20; the first to fourth power leads 32A to 32D arranged around the die pad 31; and the first to fourth wires 71 to 74 connecting the source electrode 23 to the first to fourth power leads 32A to 32D. The element head surface 20S includes the active region 40 in which a power transistor is formed and the control circuit region 50 in which the control circuit 110 configured to control the power transistor is formed. The active region 40 surrounds the control circuit region 50 from opposite sides in the X-direction and from one side in the Y-direction. The source electrode 23 is arranged on the active region 40 at a position different from the control circuit region 50. The source electrode 23 surrounds the control circuit region 50 from opposite sides in the X-direction and from one side in the Y-direction.

This structure has a greater number of paths that dissipate heat from the source electrode 23 to the control circuit region 50 than a structure in which, for example, the source electrode is located adjacent to the control circuit region 50 at only one side in the Y-direction, thereby facilitating the heat dissipation from the source electrode 23 to the control circuit region 50. As a result, occurrence of avalanche breakdown is avoided, and the avalanche withstand capability (active clamp energy capability) of the semiconductor device 10 is improved.

1-2 The source electrode 23 includes the first electrode region 23A arranged adjacent to the control circuit region 50 in the Y-direction in plan view, and the second electrode region 23B and the third electrode region 23C separately arranged at opposite sides of the control circuit region 50 in the X-direction in plan view. The semiconductor device 10 includes multiple power leads, namely, the first power lead 32A and the second power lead 32B separated from each other in the X-direction and arranged opposite from the control circuit region 50 in the Y-direction with respect to the source electrode 23; the third power lead 32C arranged in a region located at one of opposite sides of the source electrode 23 in the X-direction closer to the second electrode region 23B, and the fourth power lead 32D arranged in a region at one of opposite sides of the source electrode 23 in the X-direction closer to the third electrode region 23C. The multiple wires include the first wires 71 connecting the first electrode region 23A to the first power lead 32A, the second wires 72 connecting the first electrode region 23A to the second power lead 32B, the third wires 73 connecting the second electrode region 23B to the third power lead 32C, and the fourth wires 74 connecting the third electrode region 23C to the fourth power lead 32D.

In this structure, multiple wires are connected to each of the first to third electrode regions 23A to 23C of the source electrode 23. The wires transfer heat from the source electrode 23 to the first to fourth power leads 32A to 32D. This facilitates heat dissipation of the source electrode 23, thereby improving the avalanche withstand capability (active clamp energy capability) of the semiconductor device 10.

1-3 The width dimension WB1 of the first electrode region 23A is larger than the width dimension WB2 of the second electrode region 23B and the width dimension WB3 of the third electrode region 23C. The first wires 71 are offset from each other in the Y-direction and separated from each other in the X-direction. The second wires 72 are offset from each other in the Y-direction and separated from each other in the X-direction.

With this structure, a greater number of the first wires 71 and the second wires 72 are arranged on the first electrode region 23A than a structure in which the first wires 71 and the second wires 72 are arranged on the first electrode region 23A in a line in the X-direction. The first wires 71 and the second wires 72 facilitate the dissipation of heat from the source electrode 23.

1-4 The semiconductor device 10 further includes the heat dissipation elements 81 and 82 bonded to the source electrode 23. The heat dissipation elements 81 and 82 are arranged in the first electrode region 23A.

With this structure, heat is transferred from the first electrode region 23A to the encapsulation resin 60 through the heat dissipation elements 81 and 82. This improves the heat dissipation efficiency of the first electrode region 23A.

1-5 The heat dissipation elements include the first heat dissipation elements 81 offset from the center, in the X-direction, of the first electrode region 23A toward the second electrode region 23B and the second heat dissipation elements 82 offset from the center, in the X-direction, of the first electrode region 23A toward the third electrode region 23C.

With this structure, heat is transferred from the first electrode region 23A to the encapsulation resin 60 through the first heat dissipation elements 81 and the second heat dissipation elements 82. This improves the heat dissipation efficiency of the first electrode region 23A.

1-6 Each first wire 71 includes a first electrode connector 71A. In plan view, each first heat dissipation element 81 is arranged with respect to the first electrode connector 71A in a direction in which the first wire 71 extends.

In this structure, the first heat dissipation elements 81 are arranged in a region of the first electrode region 23A where the first wires 71 cannot be arranged. Thus, the heat dissipation efficiency of the first electrode region 23A is further improved by the first heat dissipation elements 81 while the maximum number of the first wires 71 arrangeable in the first electrode region 23A is maintained.

1-7 Each second wire 72 includes a second electrode connector 72A. In plan view, each second heat dissipation element 82 is arranged with respect to the second electrode connector 72A in a direction in which the second wire 72 extends.

In this structure, the second heat dissipation elements 82 are arranged in a region of the first electrode region 23A where the second wires 72 cannot be arranged. Thus, the heat dissipation efficiency of the first electrode region 23A is further improved by the second heat dissipation elements 82 while the maximum number of the second wires 72 arrangeable in the first electrode region 23A is maintained.

1-8 The second electrode region 23B surrounds the entirety of the control circuit region 50 in the Y-direction as viewed in the X-direction.

In this structure, heat is readily transferred from the second electrode region 23B to the entirety of the control circuit region 50 in the Y-direction. This improves the heat dissipation efficiency of the source electrode 23.

1-9 The third electrode region 23C surrounds the entirety of the control circuit region 50 in the Y-direction as viewed in the X-direction.

In this structure, heat is readily transferred from the third electrode region 23C to the entirety of the control circuit region 50 in the Y-direction. This improves the heat dissipation efficiency of the source electrode 23.

1-10 The width dimension WB2 of the second electrode region 23B is equal to the width dimension WB3 of the third electrode region 23C.

This structure reduces unevenness of heat generation amount between the second electrode region 23B and the third electrode region 23C and thus reduces the difference in temperature between the second electrode region 23B and the third electrode region 23C. This avoids a decrease in the avalanche withstand capability (active clamp energy capability), which would occur when one of the second electrode region 23B and the third electrode region 23C has an excessive temperature.

1-11 The heat dissipation elements 81 and 82 include Cu.

With this structure, the heat dissipation efficiency of the source electrode 23 is improved by the heat dissipation elements 81 and 82 as compared to a structure in which the heat dissipation elements 81 and 82 are formed from, for example, Al.

1-12 The heat dissipation elements 81 and 82 are identical in shape to the first electrode connectors 71A of the first wires 71 and the second electrode connectors 72A of the second wires 72.

With this structure, the heat dissipation elements 81 and 82 may be formed using a wire bonder that forms the first wires 71 and the second wires 72. Therefore, the heat dissipation elements 81 and 82 and the first wires 71 and the second wires 72 may be formed in a common step. This simplifies the manufacturing steps of the semiconductor device 10.

### Second Embodiment

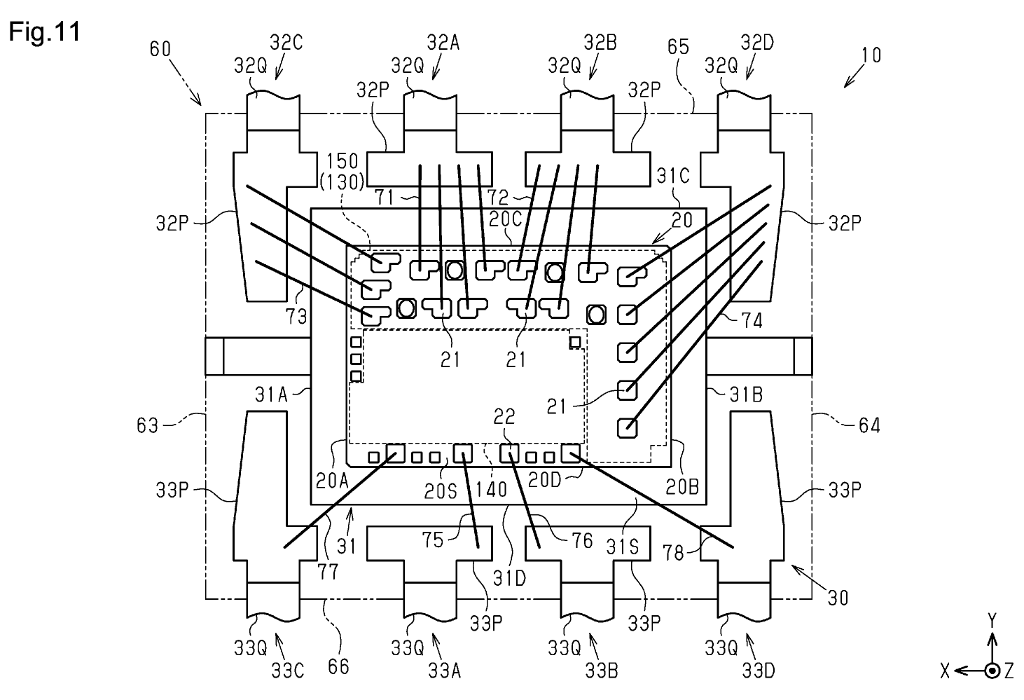

A second embodiment of a semiconductor device 10 will now be described with reference to FIGS. 11 to 15. The semiconductor device 10 of the second embodiment differs from the semiconductor device 10 of the first embodiment mainly in the internal structure of the semiconductor element 20. In the description below, differences from the semiconductor device 10 of the first embodiment will be described in detail. Same reference signs are given to those components that are the same as the corresponding components of the semiconductor device 10 of the first embodiment. Such components will not be described in detail.

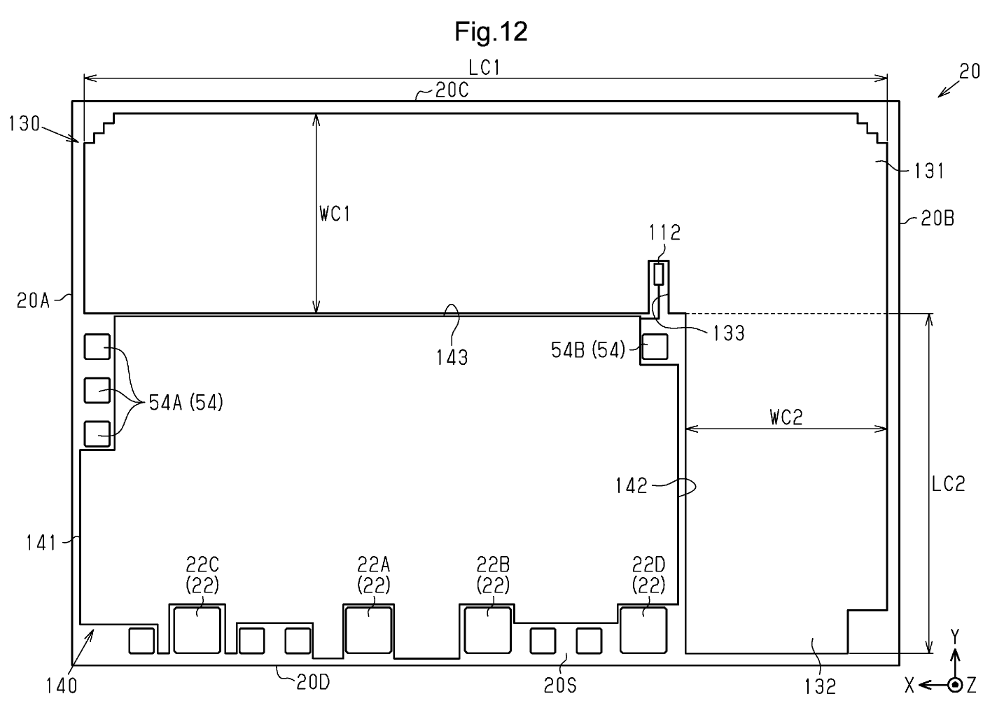

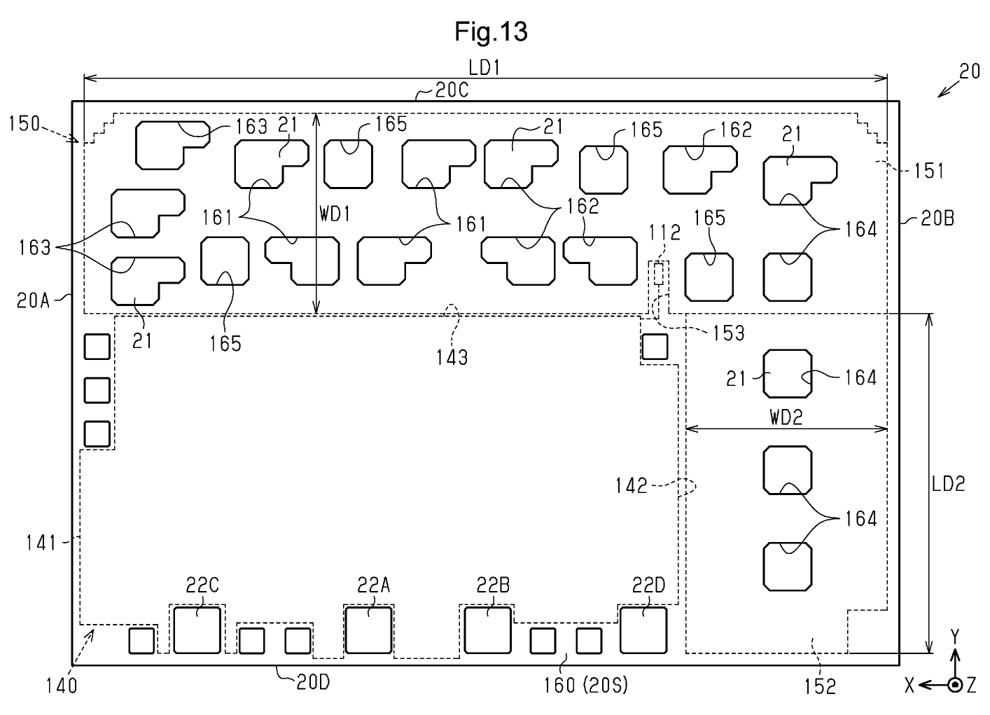

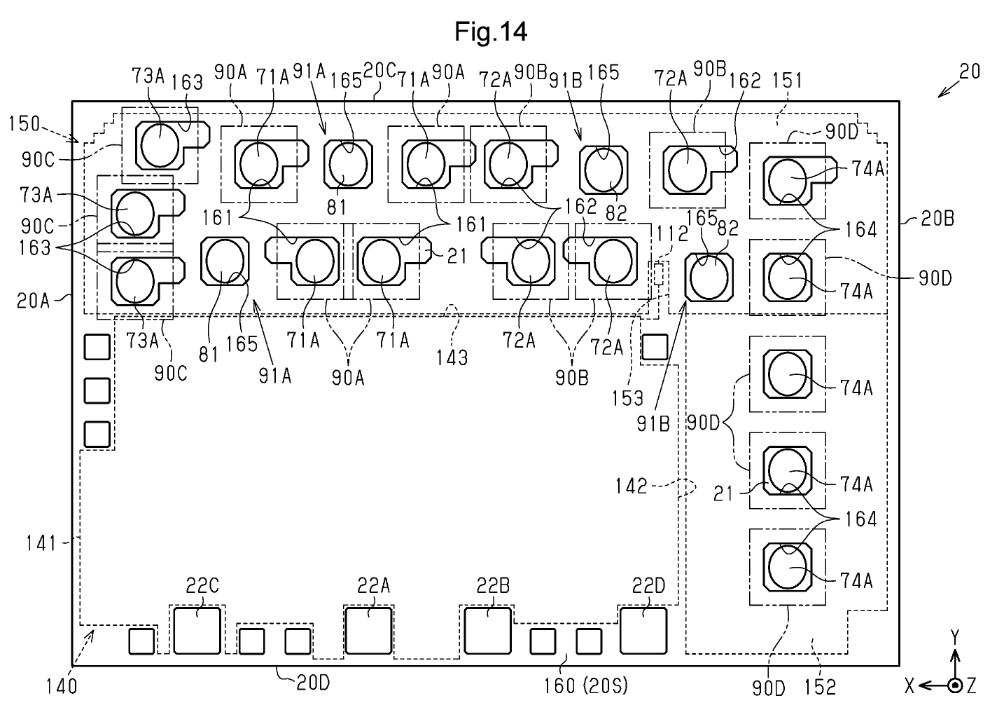

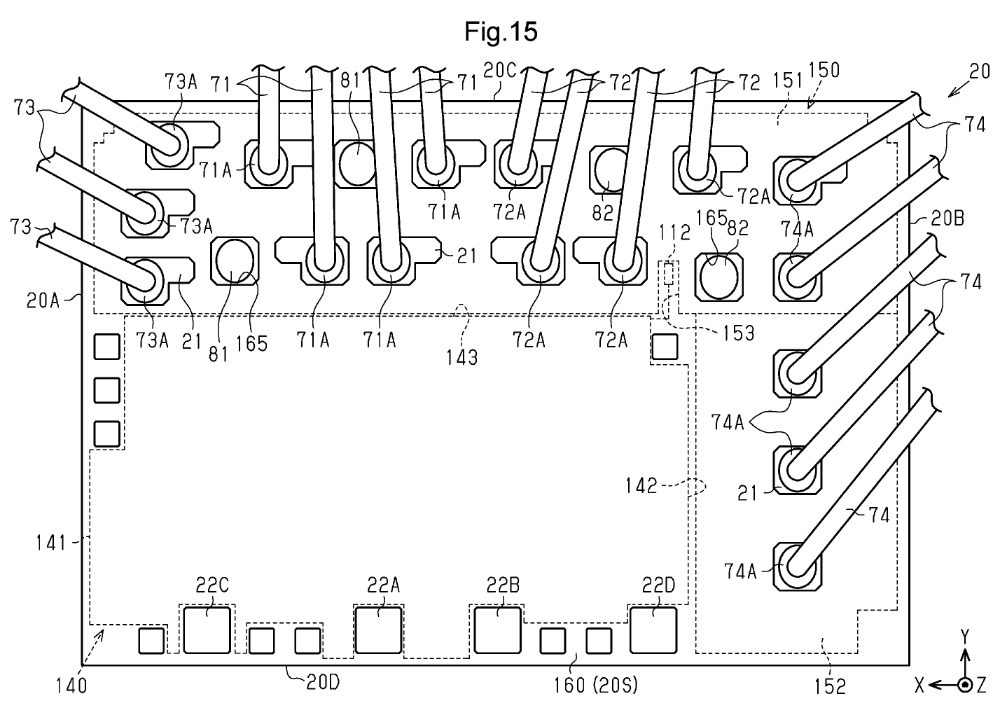

FIG. 11 is a schematic plan view of the internal structure of the semiconductor device 10. FIG. 12 is a schematic plan view of the internal structure of the semiconductor element 20. FIG. 13 is a schematic plan view of the semiconductor element 20 shown in FIG. 12, additionally showing the source electrode 23 and a passivation film 25. FIG. 14 is a schematic plan view of the semiconductor element 20 shown in FIG. 13, additionally showing the first to fourth electrode connectors 71A to 74A of the first to fourth wires 71 to 74 and the heat dissipation regions 90A to 90D. FIG. 15 is a schematic plan view of the semiconductor element 20 shown in FIG. 14, additionally showing the first to fourth wires 71 to 74. FIG. 15 does not show the heat dissipation regions 90A to 90D to facilitate understanding of the drawing.

As shown in FIG. 12, the element head surface 20S of the semiconductor element 20 includes an active region 130 in which a power transistor (in the second embodiment, power MOSFET) is formed and a control circuit region 140 in which the control circuit 110 of FIG. 5 is formed. In other words, the switching circuit 100 shown in FIG. 5 is formed in the active region 130.

The control circuit region 140 is arranged on the element head surface 20S at a position close to the first element side surface 20A and the fourth element side surface 20D. The control circuit region 140 includes first to third sides 141 to 143 as in the first embodiment. The first side 141 is located directly adjacent to the first element side surface 20A in the X-direction, which differs from the first embodiment.

In plan view, the control circuit region 140 is rectangular so that the long sides extend in the X-direction and the short sides extend in the Y-direction. In an example, the dimension of the control circuit region 140 in the X-direction is larger than or equal to 2/3 and smaller than or equal to 3/4 of the dimension of the element head surface 20S in the X-direction. In an example, the dimension of the control circuit region 140 in the Y-direction is larger than 1/2 and smaller than or equal to 2/3 of the dimension of the element head surface 20S in the Y-direction. The size of the control circuit region 140 may be changed in any manner.

In the example shown in FIG. 12, multiple (in the second embodiment, three) first inner pards 54A are arranged at a corner of the control circuit region 140 formed by the first side 141 and the third side 143. In plan view, the control circuit region 140 is recessed so as to avoid the first inner pads 54A. The first inner pads 54A are arranged next to each other in the Y-direction. A second inner pad 54B is arranged at a corner of the control circuit region 140 formed by the second side 142 and the third side 143. In plan view, the control circuit region 140 is recessed so as to avoid the second inner pad 54B. Multiple (in the second embodiment, four) control pads 22 are arranged between the control circuit region 140 and the fourth element side surface 20D in the Y-direction. The control pads 22 are located at the same position in the Y-direction and separated from each other in the X-direction. Hereinafter, the four control pads 22 are referred to as “control pads 22A to 22D.”

As shown in FIG. 11, the control pad 22A is electrically connected to the first control lead 33A by the fifth wire 75. The control pad 22B is electrically connected to the second control lead 33B by the sixth wire 76. The control pad 22C is electrically connected to the third control lead 33C by the seventh wire 77. The control pad 22D is electrically connected to the fourth control lead 33D by the eighth wire 78.

As shown in FIG. 12, in plan view, the active region 130 surrounds the control circuit region 140 from one side in the X-direction and from one side in the Y-direction. In an example, the active region 130 is L-shaped in plan view. In an example, the active region 130 may be divided into a first transistor region 131 offset from the control circuit region 140 toward the third element side surface 20C, and a second transistor region 132 located adjacent to the second side 142 of the control circuit region 140 in the X-direction. The broke line shown in the active region 130 indicates the boundary between the first transistor region 131 and the second transistor region 132.

The active region 130 surrounds the control circuit region 140 from one side in the Y-direction (side of the third element side surface 20C) with the first transistor region 131. The active region 130 surrounds the control circuit region 140 from one side in the X-direction (side of the second element side surface 20B) with the second transistor region 132.

In plan view, the second transistor region 132 is rectangular so that the long sides extend in the Y-direction and the short sides extend in the X-direction. In plan view, the second transistor region 132 has a distal edge located adjacent to the fourth element side surface 20D in the Y-direction. Therefore, the second transistor region 132 is formed adjacent, in the X-direction, to the entirety of the second side 142 of the control circuit region 140 in the Y-direction. In an example, the second transistor region 132 has a width dimension WC2 (dimension in the X-direction) that is approximately 1/4 of the dimension of the element head surface 20S in the X-direction. The first transistor region 131 has a width dimension WC1 (dimension in the Y-direction). The second transistor region 132 has a length dimension LC2 (dimension in the Y-direction) that is larger than the width dimension WC1.

The first transistor region 131 includes a region located adjacent to the third side 143 of the control circuit region 140 in the Y-direction. The first transistor region 131 is rectangular in plan view so that the long sides extend in the X-direction and the short sides extend in the Y-direction. The first transistor region 131 has a length direction LC1 (dimension in the X-direction) that is larger than the dimension of the control circuit region 140 in the X-direction. In the example shown in FIG. 12, the width dimension WC1 of the first transistor region 131 is equal to the width dimension WC2 of the second transistor region 132.

In an example, the first transistor region 131 includes a slit 133 to avoid the temperature sensor circuit 112. The slit 133 is offset from the center, in the X-direction, of the first transistor region 131 toward the second transistor region 132.

As shown in FIG. 13, the source electrode 150 is formed on the active region 130 (refer to FIG. 12). Although not shown, the source electrode 150 is formed on an insulation layer that covers the power MOSFET formed in the active region 130. The source electrode 150 is electrically connected to the power MOSFET in the active region 130 by connection lines that extend through the insulation layer in the Z-direction. Thus, the source electrode 150 is arranged on the active region 130 at a position different from the control circuit region 140.

In the example shown in FIG. 13, in plan view, the source electrode 150 is identical to the active region 130 in shape. More specifically, as shown in FIGS. 12 and 13, the source electrode 150 includes a first electrode region 151 corresponding to the first transistor region 131 and the second electrode region 152 corresponding to the second transistor region 132. In other words, the first electrode region 151 covers the first transistor region 131. The second electrode region 152 covers the second transistor region 132. Therefore, in plan view, the source electrode 150 surrounds the control circuit region 140 from one side in the X-direction (side of the second element side surface 20B) and from one side in the Y-direction (side of the third element side surface 20C). In plan view, the first electrode region 151 is located adjacent to the control circuit region 140 in the Y-direction. In plan view, the second electrode region 152 is located adjacent to the control circuit region 140 in the X-direction. The first electrode region 151 is substantially the same in size as the first transistor region 131. The second electrode region 152 is substantially the same in size as the second transistor region 132. Therefore, a width dimension WD1 (dimension in the Y-direction) of the first electrode region 151 is equal to a width dimension WD2 (dimension in the X-direction) of the second electrode region 152. A length dimension LD1 (dimension in the X-direction) of the first electrode region 151 is larger than a length dimension LD2 (dimension in the Y-direction) of the second electrode region 152.

In an example, the first electrode region 151 includes a slit 153 to avoid the temperature sensor circuit 112. The slit 153 is offset from the center, in the X-direction, of the first electrode region 151 toward the second electrode region 152. In plan view, the slit 153 overlaps the slit 133 of the first transistor region 131. Therefore, in plan view, the temperature sensor circuit 112 is exposed from the source electrode 150.

The source electrode 150 and the control circuit region 140 are, for example, covered by a passivation film 160. The passivation film 160 is a protective film protecting the semiconductor element 20 and is formed of, for example, SiN or SiO₂.

The passivation film 160 includes multiple first to fifth openings 161 to 165 over the source electrode 150. The source electrode 150 includes portions exposed in the first to fifth openings 161 to 165, defining the power pads 21 (source pads). The power pads 21 (source pads) exposed in the first to fourth openings 161 to 164 are the power pads 21 (source pads) to which the first to fourth wires 71 to 74 are connected.

The first to third openings 161 to 163 are arranged in a portion of the passivation film 160 covering the first electrode region 151.

The third openings 163 (in the second embodiment, three) are offset from the first openings 161 (in the second embodiment, four) and the second openings 162 (in the second embodiment, four) toward the first element side surface 20A in the X-direction. The third openings 163 are arranged in the Y-direction at an end of the first electrode region 151 located close to the first element side surface 20A.

Of the first openings 161, two first openings 161 are offset from the center, in the Y-direction, of the first electrode region 151 toward the third element side surface 20C. The two first openings 161 are separated from each other in the X-direction. Of the first openings 161, the remaining two first openings 161 are offset from the center, in the Y-direction, of the first electrode region 151 toward the control circuit region 140. The remaining two first openings 161 are arranged adjacent to each other in the X-direction.

The second openings 162 are offset from the first openings 161 toward the second element side surface 20B in the X-direction. Of the second openings 162, two second openings 162 are offset from the center, in the Y-direction, of the first electrode region 151 toward the third element side surface 20C. The two second openings 162 are separated from each other in the X-direction. Of the second openings 162, the remaining two second openings 162 are offset from the center, in the Y-direction, of the first electrode region 151 toward the control circuit region 140. The remaining two second openings 162 are arranged adjacent to each other in the X-direction.

The fourth openings 164 are arranged in a portion of the passivation film 160 covering the first electrode region 151 and a portion of the passivation film 160 covering the second electrode region 152. The fourth openings 164 are located at the same position in the X-direction and are separated from each other in the Y-direction. Of the fourth openings 164, two fourth openings 164 located close to the third element side surface 20C are arranged in the portion of the passivation film 160 covering the first electrode region 151. The remaining three fourth openings 164 are arranged in the portion of the passivation film 160 covering the second electrode region 152.

As shown in FIGS. 13 and 15, the first wires 71 (in the second embodiment, four) are separately connected to the power pads 21(source pads) exposed from the first openings 161. The first wires 71 are connected to the first power lead 32A (refer to FIG. 11). Each first wire 71 includes a first electrode connector 71A. As in the first embodiment, the first electrode connector 71A includes a ball bond. The first electrode connectors 71A are separated from each other in the Y-direction.

The second wires 72 (in the second embodiment, four) are separately connected to the power pads 21 (source pads) exposed from the second openings 162. The second wires 72 are connected to the second power lead 32B (refer to FIG. 11). The second wires 72 each include a second electrode connector 72A formed by ball bonding as in the first embodiment.

Of the second electrode connectors 72A, two second electrode connectors 72A are offset from the center, in the Y-direction, of the first electrode region 151 toward the third element side surface 20C. The remaining two second electrode connectors 72A are offset from the center, in the Y-direction, of the first electrode region 151 toward the control circuit region 140.

The third wires 73 (in the second embodiment, three) are separately connected to the power pads 21 (source pads) exposed from the third openings 163. The third wires 73 are connected to the third power lead 32C (refer to FIG. 11). The third wires 73 each include a third electrode connector 73A formed by ball bonding as in the first embodiment.

Of the third electrode connectors 73A, one third electrode connector 73A is offset from the center, in the Y-direction, of the first electrode region 151 toward the third element side surface 20C. One of the remaining third electrode connectors 73A is arranged in the center of the first electrode region 151 in the Y-direction. The remaining one third electrode connector 73A is offset from the center, in the Y-direction, of the first electrode region 151 toward the control circuit region 140.

The fourth wires 74 (in the second embodiment, five) are separately connected to the power pads 21 (source pads) exposed from the fourth openings 164. The fourth wires 74 are connected to the fourth power lead 32D (refer to FIG. 11). The fourth wires 74 each include a fourth electrode connector 74A formed by ball bonding as in the first embodiment.

The fourth electrode connectors 74A are located at the same position in the X-direction and are separated from each other in the Y-direction. Of the fourth electrode connectors 74A, three fourth electrode connectors 74A are arranged in the second electrode region 152, and the remaining two fourth electrode connectors 74A are arranged in the first electrode region 151. The two fourth electrode connectors 74A are arranged at one of opposite ends, in the X-direction, of the first electrode region 151 located closer to the second element side surface 20B.

As shown in FIG. 14, the heat dissipation regions 90A to 90D indicated by double-dashed lines indicate regions where heat is dissipated from the source electrode 23 via the first to fourth wires 71 to 74. Each of the heat dissipation regions 90A to 90D of the first to fourth wires 71 to 74 has the form of, for example, a rectangle centered on corresponding first to fourth electrode connectors 71A to 74A. In an example, the heat dissipation regions 90A to 90D are identical in size.

Heat dissipation regions 90A corresponding to the first wires 71 are arranged so as to surround each first electrode connector 71A in plan view. For example, adjacent ones of the heat dissipation regions 90A in the Y-direction partially overlap each other as viewed in the Y-direction.

Heat dissipation regions 90B corresponding to the second wires 72 are arranged so as to surround each second electrode connector 72A in plan view. Heat dissipation regions 90B corresponding to the two second electrode connectors 72A located close to the control circuit region 140 partially overlap each other as viewed in the X-direction.

Heat dissipation regions 90C corresponding to the third wires 73 are arranged so as to surround each third electrode connector 73A in plan view.

Heat dissipation regions 90D corresponding to the fourth wires 74 are arranged so as to surround each fourth electrode connector 74A in plan view. Therefore, the heat dissipation regions 90D are arranged next to one another in the Y-direction.

As described above, in the first electrode region 151, the first electrode connectors 71A of the first wires 71 and the second electrode connectors 72A of the second wires 72 are offset from the center of the first electrode region 151 in the Y-direction. Therefore, the first electrode region 151 includes the non-heat dissipation region 91A, which does not include the heat dissipation region 90A. In the non-heat dissipation region 91A, the temperature of the source electrode 150 increases more readily than in the heat dissipation region 90A. There are multiple (in the second embodiment, two) non-heat dissipation regions 91A. The non-heat dissipation regions 91A each have a fifth opening 165. In other words, the non-heat dissipation regions 91A include the power pads 21 (source pads), which are the source electrode 150 exposed from the passivation film 160. The first heat dissipation element 81 is arranged in each of the non-heat dissipation regions 91A. The structure of the first heat dissipation elements 81 is the same as that of the first embodiment.

As shown in FIG. 15, in plan view, one of the first heat dissipation elements 81 is arranged with respect to the first electrode connector 71A in a direction in which the first wire 71 extends. More specifically, the first heat dissipation element 81 is located adjacent to the first electrode connector 71A at a side close to the third element side surface 20C and overlaps the first wire 71 in plan view. Of the first heat dissipation elements 81, a first heat dissipation element 81 located adjacent to the first electrode connector 71A at a side close to the fourth element side surface 20D is located where the first wire 71 cannot be formed to be connected to the first power lead 32A (refer to FIG. 11). As described above, since the first wire 71 cannot be formed in the non-heat dissipation region 91A (refer to FIG. 14), the first heat dissipation element 81 is formed, instead of the first wire 71, in the non-heat dissipation region 91A.

As shown in FIG. 14, of the heat dissipation regions 90B, four heat dissipation regions 90B are offset from the center, in the Y-direction, of the first electrode region 151 in the Y-direction. Therefore, the first electrode region 151 includes the non-heat dissipation region 91B, which does not include the heat dissipation region 90B. There are multiple (in the second embodiment, two) non-heat dissipation regions 91B. The non-heat dissipation regions 91B each have a fifth opening 165. In other words, the non-heat dissipation regions 91B include the power pads 21 (source pads), which are the source electrode 150 exposed from the passivation film 25. The second heat dissipation elements 82 are arranged in each of the non-heat dissipation regions 91B in the same manner as the non-heat dissipation regions 91A.

As shown in FIG. 15, in plan view, each second heat dissipation element 82 is arranged with respect to the second electrode connector 72A in a direction in which the second wire 72 extends. Of the second heat dissipation elements 82, a second heat dissipation element 82 located adjacent to the second electrode connector 72A at a side close to the third element side surface 20C overlaps the second wire 72 in plan view. A second heat dissipation element 82 located adjacent to the second electrode connector 72A at a side close to the fourth element side surface 20D is located where the second wire 72 cannot be formed to be connected to the second power lead 32B (refer to FIG. 11). As described above, since the second wire 72 cannot be formed in the non-heat dissipation region 91B, the second heat dissipation element 82 is formed, instead of the second wire 72, in the non-heat dissipation region 91B. The first to fourth power leads 32A to 32D (refer to FIG. 11) are arranged in the same manner as the first embodiment.

### Advantages

The semiconductor device 10 of the second embodiment has the following advantages.

2-1 The semiconductor device 10 includes: the semiconductor element 20 including the element head surface 20S and the element back surface 20R facing in opposite directions, and the source electrode 150 formed on the element head surface 20S; the die pad 31 supporting the semiconductor element 20; the first to fourth power leads 32A to 32D arranged around the die pad 31; and the first to fourth wires 71 to 74 connecting the source electrode 150 to the first to fourth power leads 32A to 32D. The element head surface 20S includes the active region 130 in which a power transistor is formed and the control circuit region 140 in which the control circuit 110 configured to control the power transistor is formed. The active region 130 surrounds the control circuit region 140 from one side in the Y-direction and from one side in the X-direction. The source electrode 150 is arranged on the active region 130 at a position different from the control circuit region 140. The source electrode 150 surrounds the control circuit region 140 from one side in the Y-direction and from one side in the X-direction.

This structure has a greater number of paths that dissipate heat from the source electrode 150 to the control circuit region 140 than a structure in which, for example, the source electrode 150 is located adjacent to the control circuit region 140 at only one side in the Y-direction. Thus, heat dissipation from the source electrode 150 to the control circuit region 140 is facilitated. As a result, occurrence of avalanche breakdown is avoided, and the avalanche withstand capability (active clamp energy capability) of the semiconductor device 10 is improved.

2-2 The source electrode 150 includes the first electrode region 151 located adjacent to the control circuit region 140 in the Y-direction in plan view and the second electrode region 152 located adjacent to the control circuit region 140 in the X-direction in plan view. The semiconductor device 10 includes multiple power leads, namely, the first power lead 32A and the second power lead 32B separated from each other in the X-direction and arranged opposite from the control circuit region 140 in the Y-direction with respect to the source electrode 150, and the third power lead 32C and the fourth power lead 32D separately arranged at opposite sides of the source electrode 150 in the X-direction. The multiple wires include the first wires 71 connecting the first electrode region 151 to the first power lead 32A, the second wires 72 connecting the first electrode region 151 to the second power lead 32B, the third wires 73 connecting the first electrode region 151 to the third power lead 32C, and the fourth wires 74 connecting the second electrode region 152 to the fourth power lead 32D.

In this structure, the first to fourth wires 71 to 74 are connected to each of the first electrode region 151 and the second electrode region 152 of the source electrode 150. The first to fourth wires 71 to 74 transfer heat from the source electrode 150 to the first to fourth power leads 32A to 32D. This facilitates heat dissipation of the source electrode 150, thereby improving the avalanche withstand capability (active clamp energy capability) of the semiconductor device 10.

2-3 The first wires 71 are offset from each other in the Y-direction and separated from each other in the X-direction. The second wires 72 are offset from each other in the Y-direction and separated from each other in the X-direction.

With this structure, a greater number of the first wires 71 and the second wires 72 are arranged on the first electrode region 151 than a structure in which the first wires 71 and the second wires 72 are arranged on the first electrode region 151 in a line in the X-direction. The first wires 71 and the second wires 72 facilitate the dissipation of heat from the source electrode 150.

2-4 The first wires 71 each include a first electrode connector 71A connected to the source electrode 150. The second wires 72 each include a second electrode connector 72A connected to the source electrode 150. The semiconductor device 10 further includes the first heat dissipation element 81 arranged with respect to the first electrode connector 71A in a direction in which the first wire 71 extends in plan view, and the second heat dissipation element 82 arranged with respect to the second electrode connector 72A in a direction in which the second wire 72 extends in plan view.

In this structure, the first heat dissipation elements 81 are arranged in a region of the first electrode region 151 where the first wires 71 cannot be arranged. The second heat dissipation elements 82 are arranged in a region of the first electrode region 151 where the second wires 72 cannot be arranged. Thus, the heat dissipation efficiency of the first electrode region 151 is further improved by the first heat dissipation elements 81 and the second heat dissipation elements 82 while the maximum number of the first wires 71 and the second wires 72 arrangeable in the first electrode region 151 is maintained.

### Modified Examples

The above embodiments may be modified as described below. The modified examples described below may be combined with one another as long as there is no technical inconsistency.

In each embodiment, in plan view, the shape of the active regions 40 and 130 may be changed in any manner.

In an example, in the first embodiment, the width dimension WA1 of the first transistor region 41 may be smaller than or equal to the width dimension WA2 of the second transistor region 42. The width dimension WA1 of the first transistor region 41 may be smaller than or equal to the width dimension WA3 of the third transistor region 43. The width dimension WA2 of the second transistor region 42 may differ from the width dimension WA3 of the third transistor region 43. In an example, the width dimension WA3 of the third transistor region 43 may be larger than the width dimension WA2 of the second transistor region 42. In an example, the width dimension WA3 of the third transistor region 43 may be smaller than the width dimension WA2 of the second transistor region 42. In accordance with the changes in the active region 40 described above, the first to third electrode regions 23A to 23C of the source electrode 23 may be changed. In an example, the width dimension WB2 of the second electrode region 23B may differ from the width dimension WB3 of the third electrode region 23C.

In the second embodiment, for example, the width dimension WC1 of the first transistor region 131 may differ from the width dimension WC2 of the second transistor region 132. In an example, the width dimension WC1 of the first transistor region 131 may be larger than the width dimension WC2 of the second transistor region 132. In an example, the width dimension WC1 of the first transistor region 131 may be smaller than the width dimension WC2 of the second transistor region 132. In accordance with the changes in the active region 130 described above, the first electrode region 151 and the second electrode region 152 of the source electrode 150 may be changed. In an example, the width dimension WD1 of the first electrode region 151 may differ from the width dimension WD2 of the second electrode region 152.

In each embodiment, in plan view, the dimensional relationship between the source electrodes 23 and 150 and the control circuit regions 50 and 140 may be changed in any manner.

In an example, the length dimension LB2 of the second electrode region 23B of the source electrode 23 may be smaller than the dimension of the control circuit region 50 in the Y-direction. In an example, the length dimension LB3 of the third electrode region 23C of the source electrode 23 may be smaller than the dimension of the control circuit region 50 in the Y-direction. In an example, the length dimension LD2 of the second electrode region 152 of the source electrode 150 may be smaller than the dimension of the control circuit region 140 in the Y-direction.

In each embodiment, the size relationship in plan view between the active regions 40 and 130 and the source electrodes 23 and 150 may be changed in any manner.

In an example, the source electrodes 23 and 150 may be slightly smaller in plan view than the active regions 40 and 130. In an example, the source electrodes 23 and 150 may be slightly larger in plan view than the active regions 40 and 130.

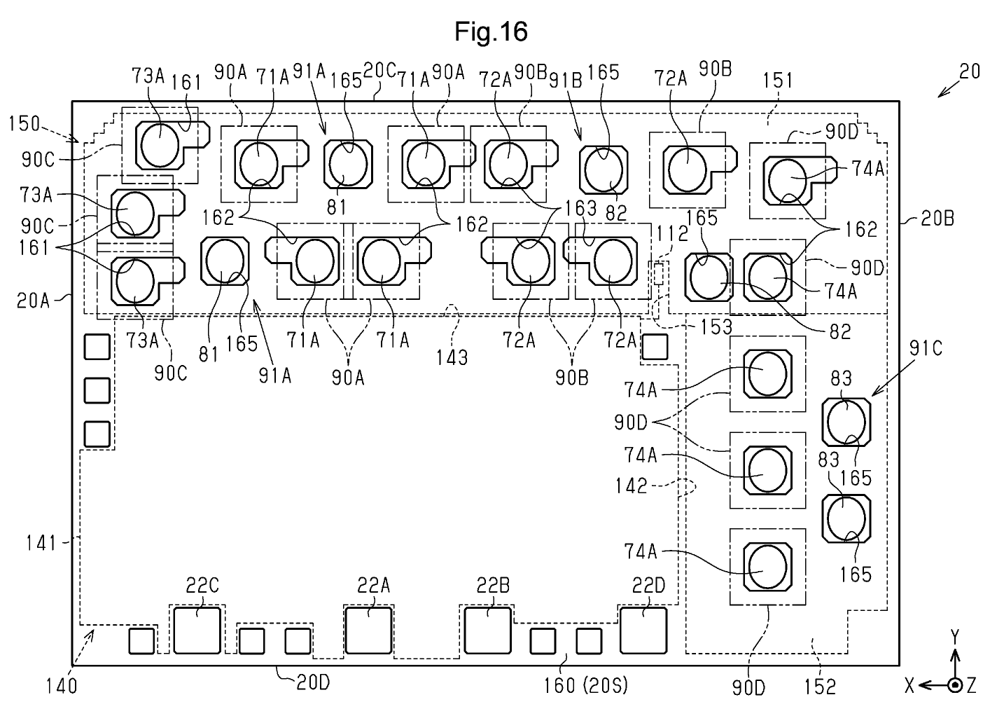

In each embodiment, the arrangement of the first to fourth wires 71 to 74 on the source electrodes 23 and 150 may be changed in any manner. In an example, in the second embodiment, as shown in FIG. 16, of the fourth electrode connectors 74A of the fourth wires 74, adjacent ones of the fourth electrode connectors 74A in the Y-direction may be offset from each other in the X-direction. In this case, the second electrode region 152 of the source electrode 150 includes a non-heat dissipation region 91C. A heat dissipation element 83 is arranged in the non-heat dissipation region 91C.

In each embodiment, the first heat dissipation elements 81 and the second heat dissipation elements 82 are not limited to ball bonds and may be changed in any manner. In an example, the first heat dissipation elements 81 and the second heat dissipation elements 82 may be obtained by bonding a pillar to the source electrodes 23 and 150. In this case, the pillar may be formed from a metal material or a material having a good heat dissipation property. Examples of the metal material include at least one of Cu, Al, Fe, Ni, and Ti. Examples of the material having a good heat dissipation property may be ceramic. The first heat dissipation elements 81 and the second heat dissipation elements 82 are not limited to a metal material and may be formed from an insulative member. As described above, the first heat dissipation elements 81 and the second heat dissipation elements 82 may differ in shape from the first to fourth electrode connectors 71A to 74A of the first to fourth wires 71 to 74.

The first heat dissipation elements 81 and the second heat dissipation elements 82 may be formed from a material differing from the first to fourth wires 71 to 74. With this structure, the first heat dissipation elements 81 and the second heat dissipation elements 82 may be formed from a material having a better heat dissipation property than the material forming the first to fourth wires 71 to 74. This increases the heat dissipation property of the non-heat dissipation regions 91A and 91B.

In each embodiment, at least one of the first heat dissipation elements 81 may be omitted.

In each embodiment, at least one of the second heat dissipation elements 82 may be omitted.

In each embodiment, the drain electrode 24 formed on the element back surface 20R of the semiconductor element 20 may be partially formed on the element back surface 20R.

In each embodiment, the structure of the semiconductor element 20 may be changed in any manner. In an example, the source electrode 23 (150) and the drain electrode 24 may be formed on the element head surface 20S of the semiconductor element 20.

In each embodiment, the entirety of the die pad 31 of the lead frame 30 may be covered by the encapsulation resin 60. That is, the die pad 31 may not be exposed from the encapsulation resin 60.

In the above embodiment, the encapsulation resin 60 may be omitted from the semiconductor device 10.

One or more of the various examples described in this specification may be combined as long as there is no technical contradiction.

In the present disclosure, the term “on” includes the meaning of “above” in addition to the meaning of “on” unless otherwise clearly indicated in the context. Accordingly, for example, the expression of “first element arranged on second element” may mean that the first element is arranged directly on the second element in one embodiment and mean that the first element is arranged above the second element without contacting the second element in another embodiment. In other words, the term “on” will also allow for a structure in which another element is formed between the first element and the second element.

The Z-direction as referred to in the present disclosure does not necessarily have to be the vertical direction and does not necessarily have to exactly coincide with the vertical direction. Accordingly, in the structures of the present disclosure, “up” and “down” in the Z-direction as referred to in this specification is not limited to “up” and “down” in the vertical direction. For example, the X-direction may be the vertical direction. Alternatively, the Y-direction may be the vertical direction.

### Clauses

The technical aspects that are understood from the present disclosure will hereafter be described. The reference signs of the components in the embodiments are given to the corresponding components in clauses with parentheses. The reference signs are used as examples to facilitate understanding, and the components in each clause are not limited to those components given with the reference signs.

### Clause A1

A semiconductor device (10), including:

a semiconductor element (20) including an element head surface (20S), an element back surface (20R) facing opposite the element head surface (20S), and a surface electrode (23) formed on the element head surface (20S);

a die pad (31) supporting the semiconductor element (20);

multiple leads (32A to 32D) arranged around the die pad (31); and

multiple wires (71 to 74) connecting the surface electrode (23) to the leads (32A to 32D), where

the element head surface (20S) includes:

an active region (40) in which a power transistor is formed; and

a control circuit region (50) in which a control circuit (110) is formed, the control circuit (110) being configured to control the power transistor,

in a direction orthogonal to a thickness direction (Z-direction) of the semiconductor element (20), a first direction (Y-direction) and a second direction (X-direction) are orthogonal to each other,

the active region (40) surrounds the control circuit region (50) from opposite sides in the second direction (X-direction) and from one side in the first direction (Y-direction),

the surface electrode (23) is arranged on the active region (40) at a position different from the control circuit region (50), and

as viewed in the thickness direction (Z-direction), the surface electrode (23) surrounds the control circuit region (50) from opposite sides in the second direction (X-direction) and from one side in the first direction (Y-direction).

### Clause A2

The semiconductor device according to clause A1, where

the surface electrode (23) includes:

a first electrode region (23A) arranged adjacent to the control circuit region (50) in the first direction (Y-direction) as viewed in the thickness direction (Z-direction); and

a second electrode region (23B) and a third electrode region (23C) separately arranged at opposite sides of the control circuit region (50) in the second direction (X-direction) as viewed in the thickness direction (Z-direction),

the leads (32A to 32D) include:

a first lead (32A) and a second lead (32B) separated from each other in the second direction (X-direction) and arranged in a region opposite from the control circuit region (50) in the first direction (Y-direction) with respect to the surface electrode (23);

a third lead (32C) arranged in a region located at one of opposite sides of the surface electrode (23) in the second direction (X-direction) closer to the second electrode region (23B); and

a fourth lead (32D) arranged in a region located at one of opposite sides of the surface electrode (23) in the second direction (X-direction) closer to the third electrode region (23C), and

the wires (71 to 74) include:

multiple first wires (71) connecting the first electrode region (23A) to the first lead (32A);

multiple second wires (72) connecting the first electrode region (23A) to the second lead (32B);

multiple third wires (73) connecting the second electrode region (23B) to the third lead (32C); and

multiple fourth wires (74) connecting the third electrode region (23C) to the fourth lead (32D).

### Clause A3

The semiconductor device according to clause A2, where

a width dimension (WB1) of the first electrode region (23A) is larger than a width dimension (WB2) of the second electrode region (23B) and a width dimension (WB3) of the third electrode region (23C),

the first wires (71) are offset from each other in the first direction (Y-direction) and separated from each other in the second direction (X-direction), and

the second wires (72) are offset from each other in the first direction (Y-direction) and separated from each other in the second direction (X-direction).

### Clause A4

The semiconductor device according to clause A3, further including:

multiple heat dissipation elements (81, 82) bonded to the surface electrode (23),

where the heat dissipation elements (81, 82) are arranged in the first electrode region (23A).

### Clause A5

The semiconductor device according to clause A4, where the heat dissipation elements include

a first heat dissipation element (81) offset from a center of the first electrode region (23A) toward the second electrode region (23B) in the second direction (X-direction), and

a second heat dissipation element (82) offset from a center of the first electrode region (23A) toward the third electrode region (23C) in the second direction (X-direction).

### Clause A6

The semiconductor device according to clause A5, where

each first wire (71) of the first wires (71) includes a first electrode connector (71A), and

as viewed in the thickness direction (Z-direction) of the semiconductor element (20), the first heat dissipation element (81) is arranged with respect to the first electrode connector (71A) in a direction in which the first wire (71) extends.

### Clause A7

The semiconductor device according to clause A5 or A6, where

each second wire (72) of the second wires (72) includes a second electrode connector (72A), and

as viewed in the thickness direction (Z-direction) of the semiconductor element (20), the second heat dissipation element (82) is arranged with respect to the second electrode connector (72A) in a direction in which the second wire (72) extends.

### Clause A8

A semiconductor device (10), including:

a semiconductor element (20) including an element head surface (20S), an element back surface (20R) facing opposite the element head surface (20S), and a surface electrode (23) formed on the element head surface (20S);

a die pad (31) supporting the semiconductor element (20);

multiple leads (32A to 32D) arranged around the die pad (31); and

multiple wires (71 to 74) connecting the surface electrode (23) to the leads (32A to 32D), where

the element head surface (20S) includes:

an active region (130) in which a power transistor is formed; and

a control circuit region (140) in which a control circuit (110) is formed, the control circuit (110) being configured to control the power transistor,

in a direction orthogonal to a thickness direction (Z-direction) of the semiconductor element (20), a first direction (Y-direction) and a second direction (X-direction) are orthogonal to each other,

the active region (130) surrounds the control circuit region (140) from one side in the first direction (Y-direction) and from one side in the second direction (X-direction),

the surface electrode (150) is arranged on the active region (130) at a position different from the control circuit region (140), and

as viewed in the thickness direction (Z-direction), the surface electrode (150) surrounds the control circuit region (140) from one side in the first direction (Y-direction) and from one side in the second direction (X-direction).

### Clause A9

The semiconductor device according to clause A8, where

the surface electrode (150) includes:

a first electrode region (151) arranged adjacent to the control circuit region (140) in the first direction (Y-direction) as viewed in the thickness direction (Z-direction); and

a second electrode region (152) arranged adjacent to the control circuit region (140) in the second direction (X-direction) as viewed in the thickness direction (Z-direction),

the leads (32A to 32D) include:

a first lead (32A) and a second lead (32B) separated from each other in the second direction (X-direction) and arranged in a region opposite from the control circuit region (140) in the first direction (Y-direction) with respect to the surface electrode (150); and

a third lead (32C) and a fourth lead (32D) separately arranged at opposite sides of the surface electrode (150) in the second direction (X-direction), and

the wires (71 to 74) include:

multiple first wires (71) connecting the first electrode region (151) to the first lead (32A);

multiple second wires (72) connecting the first electrode region (151) to the second lead (32B);

multiple third wires (73) connecting the first electrode region (151) to the third lead (32C); and

multiple fourth wires (74) connecting the second electrode region (152) to the fourth lead (32D).

### Clause A10

The semiconductor device according to clause A9, where

the first wires (71) are offset from each other in the first direction (Y-direction) and separated from each other in the second direction (X-direction), and

the second wires (72) are offset from each other in the first direction (Y-direction) and separated from each other in the second direction (X-direction).

### Clause A11

The semiconductor device according to clause A10, further including:

a first heat dissipation element (81); and

a second heat dissipation element (82), where

each first wire (71) of the first wires (71) includes a first electrode connector (71A) connected to the surface electrode (150),

as viewed in the thickness direction (Z-direction) of the semiconductor element (20), the first heat dissipation element (81) is arranged with respect to the first electrode connector (71A) in a direction in which the first wire (71) extends,

each second wire (72) of the second wires (72) includes a second electrode connector (72A) connected to the surface electrode (150), and

as viewed in the thickness direction (Z-direction) of the semiconductor element (20), the second heat dissipation element (82) is arranged with respect to the second electrode connector (72A) in a direction in which the second wire (72) extends.

### Clause A12

The semiconductor device according to clause A1 or A8, where

each wire of the wires (71 to 74) includes an electrode connector (71A to 74A) connected to the surface electrode (23/150),

a heat dissipation element (81, 82) is arranged on the surface electrode (23/150) and bonded to the surface electrode (23/150), and

the heat dissipation element (81, 82) is separated from the electrode connector (71A to 74A) of the wire (71 to 74).

### Clause A13

The semiconductor device according to clause A12, where the heat dissipation element (81, 82) is arranged adjacent to the electrode connector (71A, 72A) of the wire (71 to 74).

### Clause A14

The semiconductor device according to clause A12, where the heat dissipation element (81, 82) and the wires (71 to 74) are formed from a same material.

Clause A15

The semiconductor device according to clause A14, where the heat dissipation element (81, 82) includes Cu.

### Clause A16

The semiconductor device according to clause A15, where the heat dissipation element (81, 82) and the electrode connector (71A, 72A) are identical in shape.

### Clause A17

The semiconductor device according to any one of clauses A1 to A16, where the semiconductor element (20) includes

a source electrode (23/150) as the surface electrode formed on the element head surface (20S), and

a drain electrode (24) formed on the element back surface (20R).

### Clause A18

The semiconductor device according to clause A17, where the drain electrode (24) is formed on an entirety of the element back surface (20R).

### Clause A19

The semiconductor device according to any one of clauses A1 to A18, further including:

an encapsulation resin (60) encapsulating the semiconductor element (20) and the wires (71 to 78).

### Clause A20

The semiconductor device according to clause A19, where

the encapsulation resin (60) includes an encapsulation head surface (61) facing a same direction as the element head surface (20S) and an encapsulation back surface (62) facing opposite the encapsulation head surface (61), and

the die pad (31) is exposed from the encapsulation back surface (62).

### Clause A21

The semiconductor device according to any one of clauses A2 to A7, where the second electrode region (23B) surrounds an entirety of the control circuit region (50) in the first direction (Y-direction) as viewed in the second direction (X-direction).

### Clause A22

The semiconductor device according to any one of clauses A2 to A7, where the third electrode region (23C) surrounds an entirety of the control circuit region (50) in the first direction (Y-direction) as viewed in the second direction (X-direction).

### Clause A23

The semiconductor device according to any one of clauses A2 to A7, where a width dimension (WB2) of the second electrode region (23B) is equal to a width dimension (WB3) of the third electrode region (23C).

### Clause A24

The semiconductor device according to any one of clauses A9 to A11, where the second electrode region (152) surrounds an entirety of the control circuit region (140) in the first direction (Y-direction) as viewed in the second direction (X-direction).

### Clause A25

The semiconductor device according to clause A12 or A13, where the heat dissipation element (81, 82) is formed from a material different from the wires (71 to 78).

### Clause B1

A semiconductor element (20), including:

an element head surface (20S) including an active region (40) in which a power transistor is formed, and a control circuit region (50) in which a control circuit (110) configured to control the power transistor is formed; and

a surface electrode (23) arranged on the active region (40) at a position different from the control circuit region (50), where

a first direction (Y-direction) and a second direction (X-direction) are orthogonal to each other in a direction extending along the element head surface (20S),

the active region (40) surrounds the control circuit region (50) from opposite sides in the second direction (X-direction) and from one side in the first direction (Y-direction), and

the surface electrode (23) surrounds the control circuit region (50) from opposite sides in the second direction (X-direction) and from one side in the first direction (Y-direction).

### Clause B2

The semiconductor element according to clause B1, where the surface electrode (23) includes

a first electrode region (23A) arranged adjacent to the control circuit region (50) in the first direction (Y-direction) as viewed in a thickness direction (Z-direction) of the semiconductor element (20), and

a second electrode region (23B) and a third electrode region (23C) separately arranged at opposite sides of the control circuit region (50) in the second direction (X-direction) as viewed in the thickness direction (Z-direction).

### Clause B3

The semiconductor element according to clause B2, where the second electrode region (23B) surrounds an entirety of the control circuit region (50) in the first direction (Y-direction) as viewed in the second direction (X-direction).

### Clause B4

The semiconductor element according to clause B2 or B3, where the third electrode region (23C) surrounds an entirety of the control circuit region (50) in the first direction (Y-direction) as viewed in the second direction (X-direction).

### Clause B5

The semiconductor element according to any one of clauses B1 to B4, where the active region (40) includes

a first transistor region (41) arranged adjacent to the control circuit region (50) in the first direction (Y-direction) as viewed in a thickness direction (Z-direction) of the semiconductor element (20), and

a second transistor region (42) and a third transistor region (43) separately arranged at opposite sides of the control circuit region (50) in the second direction (X-direction) as viewed in the thickness direction (Z-direction).

### Clause B6

The semiconductor element according to clause B5, where the second transistor region (42) surrounds an entirety of the control circuit region (50) in the first direction (Y-direction) as viewed in the second direction (X-direction).

### Clause B7

The semiconductor element according to clause B5 or B6, where the third transistor region (43) surrounds an entirety of the control circuit region (50) in the first direction (Y-direction) as viewed in the second direction (X-direction).

### Clause C1

A semiconductor element (20), including:

an element head surface (20S) including an active region (130) in which a power transistor is formed, and a control circuit region (140) in which a control circuit (110) configured to control the power transistor is formed; and

a surface electrode (150) arranged on the active region (130) at a position different from the control circuit region (140), where

a first direction (Y-direction) and a second direction (X-direction) are orthogonal to each other in a direction extending along the element head surface (20S),

the active region (130) surrounds the control circuit region (140) from opposite sides in the second direction (X-direction) and from one side in the first direction (Y-direction),

the surface electrode (150) surrounds the control circuit region (140) from one side in the second direction (X-direction) and from one side in the first direction (Y-direction).

### Clause C2

The semiconductor element according to clause C1, where the surface electrode (150) includes

a first electrode region (151) arranged adjacent to the control circuit region (140) in the first direction (Y-direction) as viewed in a thickness direction (Z-direction) of the semiconductor element (20), and

a second electrode region (152) arranged adjacent to the control circuit region (140) in the second direction (X-direction) as viewed in the thickness direction (Z-direction).

### Clause C3

The semiconductor element according to clause C2, where the second electrode region (152) surrounds an entirety of the control circuit region (140) in the first direction (Y-direction) as viewed in the second direction (X-direction).

### Clause C4

The semiconductor element according to any one of clauses C1 to C3, where the active region (130) includes

a first transistor region (131) arranged adjacent to the control circuit region (140) in the first direction (Y-direction) as viewed in a thickness direction (Z-direction) of the semiconductor element (20), and

a second transistor region (132) arranged adjacent to the control circuit region (140) in the second direction (X-direction) as viewed in the thickness direction (Z-direction).

### Clause C5

The semiconductor element according to clause C4, where the second transistor region (132) surrounds an entirety of the control circuit region (140) in the first direction (Y-direction) as viewed in the second direction (X-direction).

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims.

### REFERENCE SIGNS LIST

10 semiconductor device

20 semiconductor element

20S element head surface

20R element back surface

20A to 20D first to fourth element side surfaces

21 power pad

22 control pad

23 source electrode

23A first electrode region

23AA slit

23B second electrode region

23C third electrode region

24 drain electrode

25 passivation film

25A to 25E first to fifth openings

30 lead frame

31 die pad

31S die pad head surface

31R die pad back surface

32A to 32D first to fourth power leads

33A to 33D first to fourth control leads

40 active region

41 first transistor region

42 second transistor region

43 third transistor region

44 slit

50 control circuit region

51 to 53 first to third side

54 inner pad

54A first inner pad

54B second inner pad

60 encapsulation resin

61 encapsulation head surface

62 encapsulation back surface

63 to 64 first to fourth encapsulation side surfaces

71 to 78 first to eighth wires

71A to 74A first to fourth electrode connectors

81 first heat dissipation element

82 second heat dissipation element

83 heat dissipation element

90A to 90D heat dissipation region

91A to 91C non-heat dissipation region

100 switching circuit

110 control circuit

111 current sensor circuit

112 temperature sensor circuit

113 over charge current detection circuit

114 thermal shut down circuit

115 under voltage lock out circuit

116 input terminal

117 input-side ground terminal

118 output terminal

119 output-side ground terminal

121 input line

122 ground line

200 series circuit

201 power supply

202 inductive load

130 active region

131 first transistor region

132 second transistor region

133 slit

140 control circuit region

141 to 143 first to third sides

150 source electrode

151 first electrode region

152 second electrode region

153 slit

160 passivation film

161 to 163 first to third openings

D1, D2 diodes

R1 to R4 first to fourth resistors

L coil

Sw switch

WA1 width dimension of first transistor region

WA2 width dimension of second transistor region

WA3 width dimension of third transistor region

LA1 length dimension of first transistor region

LA2 length dimension of second transistor region

LA3 length dimension of third transistor region

WB1 width dimension of first electrode region

WB2 width dimension of second electrode region

WB3 width dimension of third electrode region

LB1 length dimension of first electrode region

LB2 length dimension of second electrode region

LB3 length dimension of third electrode region

WC1 width dimension of first transistor region

WC2 width dimension of second transistor region

LC1 length dimension of first transistor region

LC2 length dimension of second transistor region

WD1 width dimension of first electrode region

WD2 width dimension of second electrode region

LD1 length dimension of first electrode region

LD2 length dimension of second electrode region

1. A semiconductor device, comprising:
a semiconductor element including an element head surface, an element back surface facing opposite the element head surface, and a surface electrode formed on the element head surface;
a die pad supporting the semiconductor element;
multiple leads arranged around the die pad; and
multiple wires connecting the surface electrode to the leads, wherein
the element head surface includes:
an active region in which a power transistor is formed; and
a control circuit region in which a control circuit is formed, the control circuit being configured to control the power transistor,
in a direction orthogonal to a thickness direction of the semiconductor element, a first direction and a second direction are orthogonal to each other,
the active region surrounds the control circuit region from opposite sides in the second direction and from one side in the first direction,
the surface electrode is arranged on the active region at a position different from the control circuit region, and
as viewed in the thickness direction, the surface electrode surrounds the control circuit region from opposite sides in the second direction and from one side in the first direction.

2. The semiconductor device according to claim 1, wherein
the surface electrode includes:
a first electrode region arranged adjacent to the control circuit region in the first direction as viewed in the thickness direction; and
a second electrode region and a third electrode region separately arranged at opposite sides of the control circuit region in the second direction as viewed in the thickness direction,
the leads include:
a first lead and a second lead separated from each other in the second direction and arranged in a region opposite from the control circuit region in the first direction with respect to the surface electrode;
a third lead arranged in a region located at one of opposite sides of the surface electrode in the second direction closer to the second electrode region; and
a fourth lead arranged in a region located at one of opposite sides of the surface electrode in the second direction closer to the third electrode region, and
the wires include:
multiple first wires connecting the first electrode region to the first lead;
multiple second wires connecting the first electrode region to the second lead;
multiple third wires connecting the second electrode region to the third lead; and
multiple fourth wires connecting the third electrode region to the fourth lead.

3. The semiconductor device according to claim 2, wherein
a width dimension of the first electrode region is larger than a width dimension of the second electrode region and a width dimension of the third electrode region,
the first wires are offset from each other in the first direction and separated from each other in the second direction, and
the second wires are offset from each other in the first direction and separated from each other in the second direction.

4. The semiconductor device according to claim 3, further comprising:
multiple heat dissipation elements bonded to the surface electrode,
wherein the heat dissipation elements are arranged in the first electrode region.

5. The semiconductor device according to claim 4, wherein the heat dissipation elements include
a first heat dissipation element offset from a center of the first electrode region toward the second electrode region in the second direction, and
a second heat dissipation element offset from a center of the first electrode region toward the third electrode region in the second direction.

6. The semiconductor device according to claim 5, wherein
each first wire of the first wires includes a first electrode connector, and
as viewed in the thickness direction of the semiconductor element, the first heat dissipation element is arranged with respect to the first electrode connector in a direction in which the first wire extends.

7. The semiconductor device according to claim 5, wherein
each second wire of the second wires includes a second electrode connector, and
as viewed in the thickness direction of the semiconductor element, the second heat dissipation element is arranged with respect to the second electrode connector in a direction in which the second wire extends.

8. A semiconductor device, comprising:
a semiconductor element including an element head surface, an element back surface facing opposite the element head surface, and a surface electrode formed on the element head surface;
a die pad supporting the semiconductor element;
multiple leads arranged around the die pad; and
multiple wires connecting the surface electrode to the leads, wherein
the element head surface includes:
an active region in which a power transistor is formed; and
a control circuit region in which a control circuit is formed, the control circuit being configured to control the power transistor,
in a direction orthogonal to a thickness direction of the semiconductor element, a first direction and a second direction are orthogonal to each other,
the active region surrounds the control circuit region from one side in the first direction and from one side in the second direction,
the surface electrode is arranged on the active region at a position different from the control circuit region, and
as viewed in the thickness direction, the surface electrode surrounds the control circuit region from one side in the first direction and from one side in the second direction.

9. The semiconductor device according to claim 8, wherein
the surface electrode includes:
a first electrode region arranged adjacent to the control circuit region in the first direction as viewed in the thickness direction; and
a second electrode region arranged adjacent to the control circuit region in the second direction as viewed in the thickness direction,
the leads include:
a first lead and a second lead separated from each other in the second direction and arranged in a region opposite from the control circuit region in the first direction with respect to the surface electrode; and
a third lead and a fourth lead separately arranged at opposite sides of the surface electrode in the second direction, and
the wires include:
multiple first wires connecting the first electrode region to the first lead;
multiple second wires connecting the first electrode region to the second lead;
multiple third wires connecting the first electrode region to the third lead; and
multiple fourth wires connecting the second electrode region to the fourth lead.

10. The semiconductor device according to claim 9, wherein
the first wires are offset from each other in the first direction and separated from each other in the second direction, and
the second wires are offset from each other in the first direction and separated from each other in the second direction.

11. The semiconductor device according to claim 10, further comprising:
a first heat dissipation element; and
a second heat dissipation element, wherein
each first wire of the first wires includes a first electrode connector connected to the surface electrode,
as viewed in the thickness direction of the semiconductor element, the first heat dissipation element is arranged with respect to the first electrode connector in a direction in which the first wire extends,
each second wire of the second wires includes a second electrode connector connected to the surface electrode, and
as viewed in the thickness direction of the semiconductor element, the second heat dissipation element is arranged with respect to the second electrode connector in a direction in which the second wire extends.

12. The semiconductor device according to claim 1, wherein
each wire of the wires includes an electrode connector connected to the surface electrode,
a heat dissipation element is arranged on the surface electrode and bonded to the surface electrode, and
the heat dissipation element is separated from the electrode connector of the wire.

13. The semiconductor device according to claim 12, wherein the heat dissipation element is arranged adjacent to the electrode connector of the wire.

14. The semiconductor device according to claim 12, wherein the heat dissipation element and the wires are formed from a same material.

15. The semiconductor device according to claim 14, wherein the heat dissipation element includes Cu.

16. The semiconductor device according to claim 15, wherein the heat dissipation element and the electrode connector are identical in shape.

17. The semiconductor device according to claim 1, wherein the semiconductor element includes
a source electrode as the surface electrode formed on the element head surface, and
a drain electrode formed on the element back surface.

18. The semiconductor device according to claim 17, wherein the drain electrode is formed on an entirety of the element back surface.

19. The semiconductor device according to claim 1, further comprising:
an encapsulation resin encapsulating the semiconductor element and the wires.

20. The semiconductor device according to claim 19, wherein
the encapsulation resin includes an encapsulation head surface facing a same direction as the element head surface and an encapsulation back surface facing opposite the encapsulation head surface, and
the die pad is exposed from the encapsulation back surface.
